(19) United States
(12) Patent Application Publication
(10) Pub. No.: US 2020/0166846 A1
(43) Pub. Date: May 28, 2020

(54) ON-PRESS DEVELOPMENT TYPE LITHOGRAPHIC PRINTING PLATE PRECURSOR AND METHOD FOR PRODUCING LITHOGRAPHIC PRINTING PLATE

(71) Applicant: FUJIFILM Corporation, Tokyo (JP)

(72) Inventors: Yusuke NAMBA, Haibara-gun (JP); Yoshiki MORITA, Haibara-gun (JP)

(73) Assignee: FUJIFILM Corporation, Tokyo (JP)

(21) Appl. No.: 16/778,806

(22) Filed: Jan. 31, 2020

Related U.S. Application Data
(63) Continuation of application No. PCT/JP2018/028353, filed on Jul. 27, 2018.

(30) Foreign Application Priority Data
Jul. 31, 2017 (JP) 2017-148558
Jun. 5, 2018 (JP) 2018-107994

(51) Int. Cl. G03F 7/30; B41N 1/08; G03F 7/09

(52) U.S. Cl. CPC G03F 7/305; G03F 7/09; B41N 1/083

(57) ABSTRACT

An on-press development type lithographic printing plate precursor including an aluminum support having an anodized film and an image-recording layer provided on the support, a shear droop shape in which an amount X of shear droop is from 25 to 150 μm and a width Y of shear droop is from 70 to 300 μm is provided on an edge portion of the lithographic printing plate precursor, and an area ratio of cracks present on a surface of the anodized film in a region corresponding to the width of shear droop Y of the lithographic printing plate precursor is 30% or less, and a method for producing a lithographic printing plate using the on-press development type lithographic printing plate precursor are provided.

### CROSS REFERENCE TO RELATED APPLICATION

This is a continuation of International Application No. PCT/JP2018/028353 filed on Jul. 27, 2018, and claims priority from Japanese Patent Application No. 2017-148558 filed on Jul. 31, 2017 and Japanese Patent Application No. 2018-107994 filed on Jun. 5, 2018, the entire disclosures of which are incorporated herein by reference.

### TECHNICAL FIELD

The present invention relates to an on-press development type lithographic printing plate precursor and a method for producing a lithographic printing plate.

### BACKGROUND OF THE INVENTION

In general, a lithographic printing plate is composed of an oleophilic image area accepting ink and a hydrophilic non-image area accepting dampening water in the process of printing. Lithographic printing is a printing method utilizing the nature of water and oily ink to repel with each other and comprising rendering the oleophilic image area of the lithographic printing plate to an ink-receptive area and the hydrophilic non-image area thereof to a dampening water-receptive area (ink-unreceptive area), thereby making a difference in adherence of the ink on the surface of the lithographic printing plate, depositing the ink only to the image area, and then transferring the ink to a printing material, for example, paper.

Currently in the plate-making process of producing a lithographic printing plate from a lithographic printing plate precursor, image exposure is performed using a CTP (computer-to-plate) technology. That is, the image exposure is directly performed by scanning exposure or the like on a lithographic printing plate precursor using a laser or a laser diode without using a lith film.

On the other hand, due to the growing interest in the global environment, an environmental problem related to a waste liquid associated with a wet type processing, for example, a development processing has been closed up as a problem of plate-making of a lithographic printing plate precursor. As a result, simplification of development processing or elimination of development processing is directed. As one simple development processing, a method referred to as “on-press development” has been proposed. The on-press development is a method of imagewise exposing a lithographic printing plate precursor, mounting the lithographic printing plate precursor on a printing press without performing a conventional wet type development processing, and then removing a non-image area of an image recording layer at an initial stage of an ordinary printing process.

In the case of printing using a lithographic printing plate, when printing on paper smaller than the size of the printing plate as in an ordinary sheet-fed printing press, an edge portion of the printing plate does not affect the printing quality, because the edge portion of the printing plate is located outside the paper. However, when printing continuously on roll paper using a rotary press as in newspaper printing, since the edge portion of the printing plate is located on the surface of the roll paper, ink attached to the edge portion is transferred to the paper to generate linear stain (edge stain), whereby the commercial value of the printed matter is significantly impaired.

As a method for preventing the occurrence of edge stain, a lithographic printing plate having an undercoat layer composed of a water-soluble compound and a light-insensitive resin layer composed of a water-insoluble resin provided on a metal support having a hydrophilic surface and having a cutting shear droop height from 20 to 100 μm at the edge portions of two sides facing each other or four sides of the support is proposed in Patent Literature 1.

Further, a lithographic printing plate precursor including an image-recording layer on a support and a water-soluble compound having a molecular weight from 60 to 300 and a solubility of 10 g/L or more in water at 20° C., in which a content of the water-soluble compound per unit area contained in a region from an edge portion to a portion inside the edge portion by 5 mm on the image-recording layer side is greater than a content of the water-soluble compound per unit area contained in a region other than the region described above by an amount of 50 mg/m² or more is proposed in Patent Literature 2.

PTL-1: JP-A-11-240268

PTL-2: WO2016/052443

### SUMMARY OF THE INVENTION

in Patent Literature 1, it is also described to set a width of shear droop to 0.1 to 0.3 mm.

However, since the lithographic printing plate described in Patent Literature 1 is used as a so-called dummy plate, unlike a conventional lithographic printing plate precursor, it has a light-insensitive resin layer composed of a resin which is soluble or swellable in an aqueous alkali solution in place of an image-recording layer. The lithographic printing plate is treated with an aqueous alkali solution in the same manner as in a conventional wet type development processing to remove the light-insensitive resin layer and then subjected to a desensitizing treatment, whereby the edge stain can be prevented.

On the contrary, in the case of an on-press development type lithographic printing plate precursor, the treatment with an aqueous alkali solution and the desensitizing treatment as described in Patent Literature 1 are not performed. Therefore, the edge stain cannot be prevented in the case of an on-press development type lithographic printing plate precursor.

In Patent Literature 2, it is also described that the lithographic printing plate precursor is subjected to plate-making by on-press development and that the lithographic printing plate precursor has a shear droop shape in which an amount X of shear droop is from 35 to 150 μm and a width Y of shear droop is from 70 to 300 μm at the edge portion thereof.

Further, in the lithographic printing plate precursor described in Patent Literature 2, in order to prevent the edge stain, the content of the water-soluble compound in the region of edge portion is increased by a method, for example, of coating a coating solution containing the water-soluble compound in the region from an edge portion to a portion inside the edge portion by 5 mm on the image-recording layer side.

However, when the region of edge portion of lithographic printing plate precursor is subjected to a hydrophilization treatment, for example, coating a coating solution containing the water-soluble compound, a problem in that the image-forming performance decreases in the region of edge portion tends to occur. It is considered that the reason for this is that the image-recording layer in the region of edge portion cannot be maintained and is removed together with the non-image area during the on-press development due to decrease in mechanical strength of the image-recording layer and decrease in adhesion between the image-recording layer and the support arising from migration of the water-soluble compound into the image-recording layer by performing the hydrophilization treatment.

The present invention provides an on-press development type lithographic printing plate precursor in which edge stain is prevented without decreasing performances, for example, on-press development property and scratch stain preventing property, and a method for producing a lithographic printing plate using the on-press development type lithographic printing plate precursor.

According to an aspect of the present disclosure, there are provided the following aspects of the invention.

(1)

An on-press development type lithographic printing plate precursor comprising an aluminum support having an anodized film and an image-recording layer provided on the support, wherein a shear droop shape in which an amount X of shear droop is from 25 to 150 Jim and a width Y of shear droop is from 70 to 300 μm is provided at an edge portion of the lithographic printing plate precursor, and an area ratio of cracks present on a surface of the anodized film in a region corresponding to the width Y of shear droop of the lithographic printing plate precursor is 30% or less.

(2)

The on-press development type lithographic printing plate precursor as recited in (1), wherein the area ratio of cracks is 10% or less.

(3)

The on-press development type lithographic printing plate precursor as recited in (2), wherein the area ratio of cracks is 6% or less.

(4)

The on-press development type lithographic printing plate precursor as recited in any one of (1) to (3), wherein an average width of cracks present on a surface of the anodized film in a region corresponding to the width Y of shear droop of the lithographic printing plate precursor is 20 μm or less.

(5)

The on-press development type lithographic printing plate precursor as recited in any one of (1) to (4), wherein an amount of the anodized film in a region corresponding to the width Y of shear droop of the lithographic printing plate precursor is from 0.5 to 5.0 g/m².

(6)

The on-press development type lithographic printing plate precursor as recited in (5), wherein the amount of the anodized film is from 0.8 to 1.2 g/m².

(7)

The on-press development type lithographic printing plate precursor as recited in any one of (1) to (6), wherein an amount of the anodized film in a region corresponding to the width Y of shear droop of the lithographic printing plate precursor is smaller than an amount of the anodized film in a region other than the region corresponding to the width of shear droop Y of the lithographic printing plate precursor.

(8)

The on-press development type lithographic printing plate precursor as recited in any one of (1) to (7), wherein an average diameter of micropores present on a surface of the anodized film in a region corresponding to the width Y of shear droop of the lithographic printing plate precursor is from 5 to 100 nm.

(9)

The on-press development type lithographic printing plate precursor as recited in any one of (1) to (7), wherein micropores of the anodized film in a region corresponding to the width Y of shear droop of the lithographic printing plate precursor are configured from a large-diameter portion extending from a surface of the anodized film to a depth of 10 to 1,000 nm and a small-diameter portion which communicates with a bottom of the large-diameter portion and extends from a communication part to a depth of 20 to 2,000 nm, and an average diameter of the small-diameter portion at the communication part is 13 nm or less.

(10)

The on-press development type lithographic printing plate precursor as recited in any one of (1) to (9), wherein the image-recording layer contains a polymer particle.

(11)

The on-press development type lithographic printing plate precursor as recited in (10), wherein the polymer particle is a polymer particle containing a monomer unit derived from a styrene compound and/or a monomer unit derived from a (meth)acrylonitrile compound.

(12)

The on-press development type lithographic printing plate precursor as recited in any one of (1) to (11), wherein the image-recording layer further contains a polymerization initiator, an infrared absorbing agent and a polymerizable compound.

(13)

A method for producing a lithographic printing plate comprising a step of imagewise exposing the on-press development type lithographic printing plate precursor as recited in any one of (1) to (12) with an infrared laser, and a step of removing an unexposed area of the image-recording layer by at least one selected from printing ink and dampening water on a printing press.

According to the present invention, an on-press development type lithographic printing plate precursor in which edge stain is prevented without decreasing performances, for example, on-press development property and scratch stain preventing property and a method for producing a lithographic printing plate using the on-press development type lithographic printing plate precursor can be provided.

### BRIEF DESCRIPTION OF DRAWINGS

FIG. 1 is a schematic view illustrating a cross-sectional shape of an edge portion of a lithographic printing plate precursor.

FIG. 2 is a conceptual view illustrating an example of a cutting portion of a slitter device.

### DETAILED DESCRIPTION

Hereinafter, mode for carrying out the invention will be described in detail.

In the specification, with respect to the description of a group in a compound represented by a formula, when the group is not indicated whether substituted or unsubstituted, unless otherwise indicated specifically, the group includes not only the unsubstituted group but also the substituted group, if the group is able to have a substituent. For example, the description “R represents an alkyl group, an aryl group or a heterocyclic group” in a formula means that R represents an unsubstituted alkyl group, a substituted alkyl group, an unsubstituted aryl group, a substituted aryl group, an unsubstituted heterocyclic group or a substituted heterocyclic group.

In the specification, the term “(meth)acrylate” means at least one of acrylate and methacrylate. The same applies to “(meth)acryloyl group”, “(meth)acrylic acid”, “(meth)acrylic resin”, and the like.

### [On-Press Development Type Lithographic Printing Plate Precursor]

The on-press development type lithographic printing plate precursor according to the invention is an on-press development type lithographic printing plate precursor which is composed of at least an aluminum support having an anodized film and an image-recording layer and which has a shear droop shape in which an amount X of shear droop is from 25 to 150 μm and a width Y of shear droop is from 70 to 300 μm provided at the edge portion thereof, and an area ratio of cracks present on a surface of the anodized film in a region corresponding to the width Y of shear droop is 30% or less.

### (Aluminum Support Having Anodized Film)

The aluminum support having an anodized film constituting the on-press development type lithographic printing plate precursor is described below.

An aluminum plate used for the aluminum support is composed of a metal containing dimensionally stable aluminum as a main component, that is, aluminum or an aluminum alloy. It is preferably selected from a pure aluminum plate and an alloy plate containing aluminum as the main component and a trace amount of foreign elements.

The foreign element contained in the aluminum alloy includes, for example, silicon, iron, manganese, copper, magnesium, chromium, zinc, bismuth, nickel and titanium. The content of the foreign element in the alloy is 10% by weight or less. A pure aluminum plate is suitable, but completely pure aluminum is difficult to manufacture in view of refining technology. Thus, an alloy plate containing slightly foreign elements may be used. The composition of the aluminum plate used for the aluminum support is not specified, and conventionally known aluminum plates, for example, JIS A 1050. JIS A 1100, JIS A 3103 or JIS A 3005 can be appropriately used.

The thickness of the aluminum plate is preferably approximately from 0.1 to 0.6 mm.

The anodized film means an anodized aluminum film which is formed on a surface of the aluminum plate by an anodizing treatment and has extremely fine pores (also referred to as micropores) which are substantially perpendicular to a surface of the film and are uniformly distributed. The micropores extend in the thickness direction from the surface of the anodized film.

### (Method for Producing Aluminum Support)

The method for producing the aluminum support is not particularly limited. A preferred aspect of the method for producing the aluminum support includes a method containing a step (roughening treatment step) in which an aluminum plate is subjected to a roughening treatment, a step (anodizing treatment step) in which the aluminum plate subjected to the roughening treatment is anodized, and a step (pore widening treatment step) in which the aluminum plate having an anodized film obtained in the anodizing treatment step is brought into contact with an aqueous acid solution or an aqueous alkali solution to increase a diameter of micropores in the anodized film.

Each step is described in detail below.

### <Roughening Treatment Step>

The roughening treatment step is a step of performing a roughening treatment including an electrochemical roughening treatment on a surface of the aluminum plate. The roughening treatment step is preferably performed before the anodizing treatment step described later, but may not be performed if the surface of the aluminum plate already has a preferred surface shape.

The roughening treatment may be performed only by an electrochemical roughening treatment, and may be performed by combining an electrochemical roughening treatment with a mechanical roughening treatment and/or a chemical roughening treatment.

In the case of combining a mechanical roughening treatment with an electrochemical roughening treatment, it is preferred to perform the electrochemical roughening treatment after the mechanical roughening treatment.

The electrochemical roughening treatment is preferably performed in an aqueous solution of nitric acid or hydrochloric acid.

The mechanical roughening treatment is commonly performed for the purpose of setting a surface roughness Ra of the surface of the aluminum plate to 0.35 to 1.0 μm.

The conditions of the mechanical roughening treatment are not particularly limited. For example, the mechanical roughening treatment can be performed according to the method described in JP-B-50-40047. The mechanical roughening treatment can be performed by a brush grain treatment using a pumice stone suspension or can be performed by a transfer method.

Further, the chemical roughening treatment is not particularly limited, and can be performed according to a known method.

After the mechanical roughening treatment, the chemical etching treatment described below is preferably performed.

The chemical etching treatment performed after the mechanical roughening treatment is carried out for smoothing edge parts of uneven shapes on the surface of the aluminum plate to prevent ink from being caught during printing, thereby improving stain resistance of a lithographic printing plate, and for removing unnecessary substances, for example, abrasive particles remaining on the surface.

As the chemical etching treatment, etching using an acid and etching using an alkali are known. A method particularly excellent in view of etching efficiency includes a chemical etching treatment using an alkali solution (hereinafter, also referred to as an “alkali etching treatment”).

An alkali agent used in the alkali solution is not particularly limited but suitably includes, for example, sodium hydroxide, potassium hydroxide, sodium metasilicate, sodium carbonate, sodium aluminate and sodium gluconate.

Further, the alkali solution may contain aluminum ions. The concentration of the alkali solution is preferably 0.01% by weight or more, and more preferably 3% by weight or more, but preferably 30% by weight or less, and more preferably 25% by weight or less.

Further, the temperature of the alkali solution is preferably room temperature or higher, and more preferably 30° C. or higher, but preferably 80° C. or lower, and more preferably 75° C. or lower.

The etching amount is preferably 0.1 g/m² or more, and more preferably 1 g/m² or more, but preferably 20 g/m² or less, and more preferably 10 g/m² or less.

Further, the treatment time is preferably from 2 seconds to 5 minutes depending on the etching amount, and more preferably from 2 to 10 seconds in view of improving the productivity.

In the case where the alkali etching treatment is performed after the mechanical roughening treatment, a chemical etching treatment using an acidic solution of a low temperature (hereinafter, also referred to as “desmut treatment”) is preferably performed to order to remove substances produced by the alkali etching treatment.

An acid used in the acidic solution is not particularly limited and includes, for example, sulfuric acid, nitric acid and hydrochloric acid. The concentration of the acidic solution is preferably from 1 to 50% by weight. The temperature of the acidic solution is preferably from 20 to 80 C. When the concentration and temperature of the acidic solution fall within the ranges described above, spot-like stain resistance is more improved in a lithographic printing plate obtained using the aluminum support.

The roughening treatment described above is a treatment in which an electrochemical roughening treatment is performed after a mechanical roughening treatment and a chemical etching treatment, if desired, but in the case where the electrochemical roughening treatment is performed without performing the mechanical roughening treatment, the chemical etching treatment can be performed using an aqueous alkali solution, for example, sodium hydroxide before the electrochemical roughening treatment. Thereby, impurities and the like present in the vicinity of the surface of the aluminum plate can be removed.

The electrochemical roughening treatment is suitable for producing a lithographic printing plate having excellent printability because it is easy to impart fine irregularities (pits) to the surface of the aluminum plate.

The electrochemical roughening treatment is performed using direct current or alternating current in an aqueous solution mainly composed of nitric acid or hydrochloric acid.

Further, after the electrochemical roughening treatment, the chemical etching treatment described below is preferably performed. Smut and intermetallic compounds are present on the surface of the aluminum plate after the electrochemical roughening treatment. In the chemical etching treatment performed after the electrochemical roughening treatment, it is preferred to first perform a chemical etching treatment using an alkali solution (alkali etching treatment) in order to efficiently remove particularly smut. As to the conditions of the chemical etching treatment using an alkali solution, the treatment temperature is preferably from 20 to 80° C. and the treatment time is preferably from 1 to 60 seconds. Further, it is preferred that the alkali solution contains aluminum ions.

Moreover, in the case where the chemical etching treatment using an alkali solution is performed after the electrochemical roughening treatment, a chemical etching treatment using an acidic solution of a low temperature (desmut treatment) is preferably performed in order to remove substances produced by the chemical etching treatment using an alkali solution.

Further, even in the case where the alkali etching treatment is not performed after the electrochemical roughening treatment, the desmut treatment is preferably performed in order to remove smut efficiently.

Any of the chemical etching treatments described above can be performed by a dipping method, a shower method, a coating method or the like, and is not particularly limited.

### <Anodizing Treatment Step>

The anodizing treatment step is a step in which an aluminum oxide film having micropores extending in the depth direction (thickness direction) is formed on the surface of the aluminum plate by performing an anodizing treatment to the aluminum plate which has been subjected to the roughening treatment. By the anodizing treatment, an aluminum anodized film having micropores is formed on the surface of the aluminum plate.

The anodizing treatment can be performed by a method conventionally used in this field, and the manufacturing conditions are appropriately set so that the micropores described above can be finally formed. Specifically, the average diameter (average opening diameter) of the micropores formed in the anodizing treatment step is usually approximately from 4 to 14 nm, and preferably from 5 to 10 nm. Within the range described above, micropores having a predetermined shape can be easily formed, and the performances of the lithographic printing plate precursor and lithographic printing plate obtained are further improved.

Further, the depth of the micropore is usually approximately 10 nm or more and less than 100 nm, and preferably from 20 to 60 nm. Within the range described above, micropores having a predetermined shape can be easily formed, and the performances of the lithographic printing plate precursor and lithographic printing plate obtained are further improved.

The pore density of the micropore is not particularly limited, and the pore density is preferably from 50 to 4,000/μm², and more preferably from 100 to 3,000/μm². Within the range described above, the lithographic printing plate precursor obtained is excellent in the on-press development property, and the lithographic printing plate obtained is excellent in printing durability and deinking ability after suspended printing.

In the anodizing treatment step, an aqueous solution of sulfuric acid, phosphoric acid, oxalic acid or the like can be mainly used as an electrolytic bath. Depending on the case, chromic acid, sulfamic acid, benzenesulfonic acid or the like, or an aqueous solution or non-aqueous solution in which two or more of these are combined may be used. When direct current or alternating current is passed through the aluminum plate in the electrolytic bath, an anodized film can be formed on the surface of the aluminum plate. The electrolytic bath may contain aluminum ions. The content of the aluminum ion in the electrolytic bath is not specifically limited, and is preferably from 1 to 10 g/L.

The conditions of the anodizing treatment are appropriately set depending on the electrolytic solution used. In general, it is appropriate that the concentration of the electrolytic solution is from 1 to 80% by weight (preferably from 5 to 20% by weight), the solution temperature is from 5 to 70° C. (preferably from 10 to (6° C.), the current density is from 0.5 to 60 A/dm² (preferably 5 to 50 A/dm²), the voltage is from 1 to 100 V (preferably from 5 to 50 V), and the electrolysis time is from 1 to 100 seconds (preferably from 5 to 60 seconds).

Among these anodizing treatments, a method of anodizing at a high current density in sulfuric acid described in British Patent 1,412,768 is particularly preferred.

The anodizing treatment can also be performed a plurality of times. One or more conditions, for example, the kind of the electrolytic solution, concentration, solution temperature, current density, voltage, and electrolysis time used in each anodizing treatment can be changed. When the number of anodizing treatments is two, a first time anodizing treatment may be referred to as a first anodizing treatment and a second time anodizing treatment may be referred to as a second anodizing treatment. By performing the first anodizing treatment and the second anodizing treatment, anodic oxide films having different shapes can be produced, and a lithographic printing plate precursor having excellent printing performance can be provided.

Furthermore, the pore widening treatment described below can be performed following the anodizing treatment, and then an anodizing treatment can be performed again. In this case, the first anodizing treatment, the pore widening treatment and the second anodizing treatment are performed.

The shape of the micropore formed by the anodizing treatment is ordinarily an approximately straight tubular shape (approximately cylindrical shape) in which the diameter of the micropore does not approximately change in the depth direction (thickness direction), and may be a conical shape in which the diameter continuously decreases in the depth direction (thickness direction). Further, it may be a shape in which the diameter discontinuously decreases in the depth direction (thickness direction).

The micropore having a shape in which the diameter discontinuously decreases in the depth direction (thickness direction) specifically includes a micropore configured from a large-diameter portion which extends from a surface of the anodized film in the depth direction and a small-diameter portion which communicates with a bottom of the large-diameter portion and extends from the communication part in the depth direction. In order to form micropore having such a shape, the method of performing the first anodizing treatment, the pore widening treatment and the second anodizing treatment described above can be used.

In the micropore having the large-diameter portion and the small-diameter portion, the average diameter of the large-diameter portion at the surface of the anodized film is from 10 to 100 nm, and preferably from 15 to 60 nm.

The large-diameter portion is a hole portion extending 10 to 1,000 nm in the depth direction (thickness direction) from the surface of the anodized film. The depth is preferably from 10 to 200 nm.

The bottom of the large-diameter portion is located at 10 to 1,000 nm in the depth direction (thickness direction) from the surface of the anodized film.

The shape of the large-diameter portion is not particularly limited and includes, for example, an approximately straight tubular shape (approximately cylindrical shape) and a conical shape in which the diameter continuously decreases in the depth direction (thickness direction). The approximately straight tubular shape is preferred.

The small-diameter portion is a hole portion which communicates with the bottom of the large-diameter portion and extends 20 to 2,000 nm in the depth direction (thickness direction) from the communication part. The depth is preferably from 300 to 1,500 nm.

The average diameter of the small-diameter portion at the communication part is preferably 13 nm or less, and more preferably 11 nm or less. The lower limit thereof is not particularly limited and is ordinarily 8 nm.

The shape of the small-diameter portion is not particularly limited and includes, for example, an approximately straight tubular shape (approximately cylindrical shape) and a conical shape in which the diameter continuously decreases in the depth direction (thickness direction). The approximately straight tubular shape is preferred.

As the micropore having a large-diameter portion and a small-diameter portion, a micropore configured from a large-diameter portion extending from a surface of the anodized film to a depth of 10 to 1,000 nm and a small-diameter portion which communicates with a bottom of the large-diameter portion and extends from the communication part to a depth of 20 to 2,000 nm, and an average diameter of the small-diameter portion at the communication part is 13 nm or less is preferred from the standpoint of adjusting an area ratio of cracks present at the surface of the anodized film to 30% or less and/or adjusting the average width of cracks to 20 μm or less in a region corresponding to the width Y of shear droop according to the invention.

### <Pore Widening Treatment Step>

The pore widening treatment step is a step of performing a treatment (pore diameter enlargement treatment) for enlarging the diameter (pore diameter) of the micropore present in the anodized film formed by the anodizing treatment step described above. By the pore widening treatment, the diameter of the micropore is enlarged, and an anodized film having micropores having a larger average diameter is formed.

The pore widening treatment is performed by bringing the aluminum plate obtained by the anodizing treatment step described above into contact with an aqueous acid solution or an aqueous alkali solution. The contact method is not particularly limited and includes, for example, an immersion method and a spray method. Among these, the immersion method is preferred.

In the case of using an aqueous alkali solution in the pore widening treatment step, it is preferred to use an aqueous alkali solution containing at least one selected from the group consisting of sodium hydroxide, potassium hydroxide and lithium hydroxide. The concentration of the aqueous alkali solution is preferably from 0.1 to 5% by weight. It is appropriate that after adjusting the pH of the aqueous alkali solution to 11 to 13, the aluminum plate is brought into contact with the aqueous alkali solution for from 1 to 300 seconds (preferably from 1 to 50 seconds) under conditions of from 10 to 70° C. (preferably from 20 to 50° C.). At this time, the aqueous alkali solution may contain a metal salt of a polyvalent weak acid, for example, a carbonate, a borate or a phosphate.

In the case of using an aqueous acid solution in the pore widening treatment step, it is preferred to use an aqueous solution of an inorganic acid, for example, sulfuric acid, phosphoric acid, nitric acid or hydrochloric acid, or a mixture thereof. The concentration of the aqueous acid solution is preferably from 1 to 80% by weight, and more preferably from 5 to 50% by weight. It is appropriate that the aluminum plate is brought into contact with the aqueous acid solution for from 1 to 300 seconds (preferably from 1 to 150 seconds) under conditions of from 5 to 70° C. (preferably from 10 to 60° C.). The aqueous alkali solution or the aqueous acid solution may contain aluminum ions. The content of the aluminum ion is not particularly limited and is preferably from 1 to 10 g/L.

### <Pore Widening Treatment Step at Edge Portion>

It is also preferred that the pore widening treatment step is performed only in a partial region (edge portion) on the support. By performing the pore widening treatment not on the entire surface of the support but on a partial region of the support, decrease in the scratch resistance can be prevented.

As a method for performing the pore widening treatment only in the partial region, a known method, for example, a die coating method, a dip coating method, an air knife coating method, a curtain coating method, a roller coating method, a wire bar coating method, a gravure coating method, a slide coating method, an inkjet coating method, a dispenser coating method or a spray method can be used. Since a part of the support is required to be coated with the aqueous acid solution or aqueous alkali solution, the inkjet coating method or the dispenser coating method is preferred. Further, it is preferred that the region to be coated corresponds to two sides facing each other of a lithographic printing plate precursor after cutting.

The aqueous acid solution or aqueous alkali solution may be coated from the edge portion of the support or may be coated on a position other than the edge portion of the support. Further, a combination of the positions to be coated may be used. It is preferred to coat in a strip having a fixed width in any of the cases of coating from the edge portion of the support and coating on a position other than the edge portion of the support. A preferred coating width is from 1 to 50 mm. It is preferred to cut the coating region having the coating width so that the coating region is present within 1 cm from an edge portion after the cutting. The cutting may be performed at one place of the coating region or two places of the same coating region.

### <Hydrophilizing Treatment Step>

The method for producing the aluminum support may include a hydrophilizing treatment step performing hydrophilizing treatment after the pore widening treatment step described above. The hydrophilizing treatment may be performed by a known method disclosed in paragraphs 0109 to 0114 of JP-A-2005-254638.

It is preferred to perform the hydrophilizing treatment by a method of immersing in an aqueous solution of an alkali metal silicate, for example, sodium silicate or potassium silicate or a method of coating a hydrophilic vinyl polymer or a hydrophilic compound to form a hydrophilic undercoat layer.

The hydrophilizing treatment with an aqueous solution of an alkali metal silicate, for example, sodium silicate or potassium silicate can be performed according to the methods and procedures described in U.S. Pat. Nos. 2,714,066 and 3,181,461.

### PREFERRED EMBODIMENT

The aluminum support may have, if desired, a backcoat layer containing an organic polymer compound described in JP-A-5-45885, an alkoxy compound of silicon described in JP-A-6-35174 or the like on the surface opposite to the image recording layer.

### [Image-Recording Layer]

The image-recording layer constituting the on-press development type lithographic printing plate precursor is described below.

### <Polymer Particles>

The image-recording layer preferably contains polymer particles. The polymer particles contribute to improvement in the on-press development property. The polymer particles are preferably polymer particles which can convert the image-recording layer to hydrophobic when heat is applied. The polymer particles are preferably at least one selected from hydrophobic thermoplastic polymer particles, heat-reactive polymer particles, polymer particles having a polymerizable group, microcapsules containing a hydrophobic compound and microgel (crosslinked polymer particles).

The hydrophobic thermoplastic polymer particles suitably include, for example, hydrophobic thermoplastic polymer particles described in Research Disclosure No. 33303, January 1992, JP-A-9-123387, JP-A-9-131850, JP-A-9-171249, JP-A-9-171250 and European Patent 931,647.

Specific examples of the polymer constituting the hydrophobic thermoplastic polymer particles include a homopolymer or copolymer of a monomer, for example, ethylene, styrene, vinyl chloride, methyl acrylate, ethyl acrylate, methyl methacrylate, ethyl methacrylate, vinylidene chloride, acrylonitrile, vinyl carbazole or an acrylate or methacrylate having a polyalkylene structure, and a mixture thereof. Preferably, polystyrene, a copolymer containing styrene and acrylonitrile and polymethyl methacrylate are used. The average particle diameter of the hydrophobic thermoplastic polymer particles is preferably from 0.01 to 2.0 μm.

The thermally reactive polymer particles include polymer particles having a thermally reactive group. The polymer particles having a thermally reactive group form a hydrophobized region by crosslinking by a thermal reaction and a functional group conversion at that time.

The thermally reactive group in the polymer particles having a thermally reactive group may be a functional group which undergoes any reaction as long as a chemical bond is formed and is preferably a polymerizable group. Suitable examples thereof include an ethylenically unsaturated group which undergoes a radical polymerization reaction (for example, an acryloyl group, a methacryloyl group, a vinyl group or an allyl group), a cationic polymerizable group (for example, a vinyl group, a vinyloxy group, an epoxy group or an oxetanyl group), an isocyanato group which undergoes an addition reaction or a block form thereof, an epoxy group, a vinyloxy group and a functional group having an active hydrogen atom (for example, an amino group, a hydroxy group or a carboxyl group) as the reaction partner thereof, a carboxyl group which undergoes a condensation reaction and a hydroxy group or amino group as the reaction partner thereof, an acid anhydride which undergoes a ring-opening addition reaction and an amino group or a hydroxy group as the reaction partner thereof.

The microcapsules include microcapsules in which all or part of the constituent components of the image-recording layer are encapsulated as described, for example, in JP-A-2001-277740 and JP-A-2001-277742. The constituent components of the image-recording layer may be present outside the microcapsules. The image-recording layer containing microcapsules preferably has an aspect in which hydrophobic constituent components are encapsulated in microcapsules and hydrophilic constituent components are present outside the microcapsules.

The microgel (crosslinked polymer particles) can contain a part of the constituent components of the image-recording layer at least one of in the inside and on the surface thereof. In particular, an aspect of a reactive microgel having a radical polymerizable group on the surface thereof is preferred from the standpoint of image-forming sensitivity and printing durability.

Known methods can be used for microencapsulation or microgelation of the constituent components of the image-recording layer.

The average particle diameter of the microcapsule or microgel is preferably from 0.01 to 3.0 μm, more preferably from 0.05 to 2.0 μm, and particularly preferably from 0.10 to 1.0 μm. In the range described above, good resolution and good preservation stability can be achieved.

The polymer particles are preferably polymer particles containing a monomer unit derived from a styrene compound and/or a monomer unit derived from a (meth)acrylonitrile compound from the standpoint of contribution to the on-press development property. Further, particles of polymer further containing a monomer unit derived from a poly(ethylene glycol) alkyl ether methacrylate compound are preferred.

The polymer particles may be used one kind alone or in combination of two or more kinds.

The content of the polymer particles is preferably from 5 to 90% by weight, more preferably from 5 to 80% by weight, and still more preferably from 10 to 75% by weight based on the total solid content of the image-recording layer.

The image-recording layer preferably contains a polymerization initiator, an infrared absorbing agent and a polymerizable compound.

### <Polymerization Initiator>

The polymerization initiator is a compound which generates a polymerization initiation species, for example, a radical or a cation by energy of light, heat or both, and can be used by appropriately selecting from a known thermal polymerization initiator, a compound having a bond having a small bond dissociation energy, a photopolymerization initiator, and the like.

The polymerization initiator is preferably an infrared-sensitive polymerization initiator. In addition, the polymerization initiator is preferably a radical polymerization initiator. Two or more radical polymerization initiators may be used in combination.

The radical polymerization initiator may be either an electron-accepting polymerization initiator or an electron-donating polymerization initiator.

### (Electron-Accepting Polymerization Initiator)

The electron-accepting polymerization initiator includes, for example, an organic halide, a carbonyl compound, an azo compound, an organic peroxide, a metallocene compound, an azide compound, a hexaarylbiimidazole compound, a disulfone compound, an oxime ester compound and an onium salt compound.

As the organic halide, for example, compounds described in paragraphs 0022 and 0023 of JP-A-2008-195018 are preferred.

As the carbonyl compound, for example, compounds described in paragraph 0024 of JP-A-2008-195018 are preferred.

The azo compound includes, for example, azo compounds described in JP-A-8-108621.

As the organic peroxide, for example, compounds described in paragraph 0025 of JP-A-2008-195018 are preferred.

As the metallocene compound, for example, compounds described in paragraph 0026 of JP-A-2008-195018 are preferred.

The azide compound includes, for example, 2,6-bis(4-azidobenzylidene)-4-methylcyclohexanone.

As the hexaarylbiimidazole compound, for example, compounds described in paragraph 0027 of JP-A-2008-195018 are preferred.

The disulfone compound includes, for example, compounds described in JP-A-61-166544 and JP-A-2002-328465.

As the oxime ester compound, for example, compounds described in paragraphs 0028 to 0030 of JP-A-2008-195018 are preferred.

Of the electron-accepting polymerization initiators, an onium salt, for example, an iodonium salt, a sulfonium salt or an azinium salt is more preferred. Iodonium salt and sulfonium salt are particularly preferred. Specific examples of the iodonium salt and sulfonium salt are shown below, but the invention is not limited thereto.

As the iodonium salt, a diphenyl iodonium salt is preferred, in particular, a diphenyl iodonium salt having an electron-donating group as a substituent, for example, a diphenyl iodonium salt substituted with an alkyl group or an alkoxy group is preferred, and an asymmetric diphenyl iodonium salt is also preferred. Specific examples thereof include diphenyliodonium hexafluorophosphate, 4-methoxyphenyl-4-(2-methylpropyl)phenyliodonium hexafluorophosphate, 4-(2-methylpropyl)phenyl-p-tolyliodonium hexafluorophosphate, 4-hexyloxyphenyl-2,4,6-trimethoxyphenyliodonium hexafluorophosphate, 4-hexyloxyphenyl-2,4-diethoxyphenyliodonium tetrafluoroborate, 4-octyloxyphenyl-2,4,6-trimethoxyphenyliodonium 1-perfluorobutanesulfonate, 4-octyloxyphenyl-2,4,6-trimethoxyphenyliodonium hexafluorophosphate, and bis(4-tert-butylphenyl)iodonium hexafluorophosphate.

As the sulfonium salt, a triarylsulfonium salt is preferred, and in particular, a triarylsulfonium salt having an electron-withdrawing group as a substituent, for example, at least a part of the groups on the aromatic ring is substituted with a halogen atom is preferred. Further, a triarylsulfonium salt in which the total substitution number of halogen atoms on the aromatic ring is 4 or more is more preferred. Specific examples thereof include triphenylsulfonium hexafluorophosphate, triphenylsulfonium benzoyl formate, bis(4-chlorophenyl)phenylsulfonium benzoyl formate, bis(4-chlorophenyl)-4-methylphenylsulfonium tetrafluoroborate, tris(4-chlorophenyl)sulfonium 3,5-bis(methoxycarbonyl)benzenesulfonate, tris(4-chlorophenyl)sulfonium hexafluorophosphate, and tris(2,4-dichlorophenyl)sulfonium hexafluorophosphate.

The electron-accepting polymerization initiators may be used one kind alone or in combination of two or more kinds.

The content of the electron-accepting polymerization initiator is preferably from 0.1 to 50% by weight, more preferably from 0.5 to 30% by weight, and still more preferably from 0.8 to 20% by weight based on the total solid content of the image-recording layer.

### (Electron-Donating Polymerization Initiator)

The electron-donating polymerization initiator contributes to improvement in the printing durability of a lithographic printing plate produced from the lithographic printing plate precursor. The electron-donating polymerization initiator includes, for example, five kinds described below. (i) Alkylate or arylate complex: It is believed that a carbon-hetero bond is oxidatively cleaved to generate an active radical. Specific examples thereof include a borate compound. (ii) Aminoacetic acid compound: It is believed that the C—X bond on carbon adjacent to nitrogen is cleaved by oxidation to generate an active radical. X is preferably a hydrogen atom, a carboxyl group, a trimethylsilyl group or a benzyl group. Specific examples thereof include an N-phenylglycine (which may have a substituent on the phenyl group), and an N-phenyliminodiacetic acid (which may have a substituent on the phenyl group). (iii) Sulfur-containing compound: A compound obtained by replacing the nitrogen atom of the aminoacetic acid compound described above with a sulfur atom can generate an active radical by the same action. Specific examples thereof include a phenylthioacetic acid (which may have a substituent on the phenyl group). (iv) Tin-containing compound: A compound in which the nitrogen atom of the aminoacetic acid compound described above is replaced with a tin atom can generate an active radical by the same action. (v) Sulfinic acid salt: An active radical can be generated by oxidation. Specific examples thereof include sodium arylsufinate.

Of the electron-donating polymerization initiators, a borate compound is preferred. As the borate compound, a tetraaryl borate compound or a monoalkyl triaryl borate compound is preferred, and the tetraaryl borate compound is more preferred from the standpoint of compound stability.

The counter cation in the borate compound is preferably an alkali metal ion or a tetraalkylammonium ion, and more preferably a sodium ion, a potassium ion or a tetrabutylammonium ion.

Specific examples of the borate compound include compounds shown below. Here, X_{c}⁺ represents a monovalent cation, preferably an alkali metal ion or a tetraalkylammonium ion, and more preferably an alkali metal ion or a tetrabutylammonium ion. Bu represents an n-butyl group.

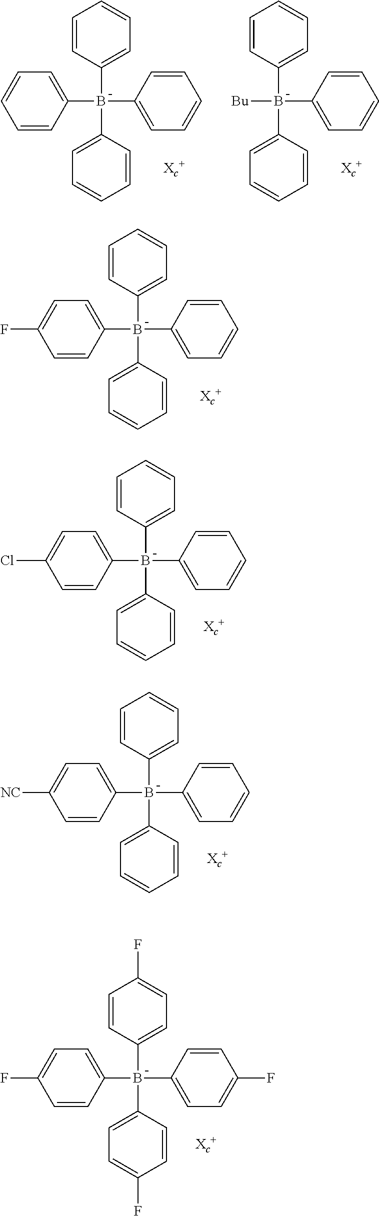

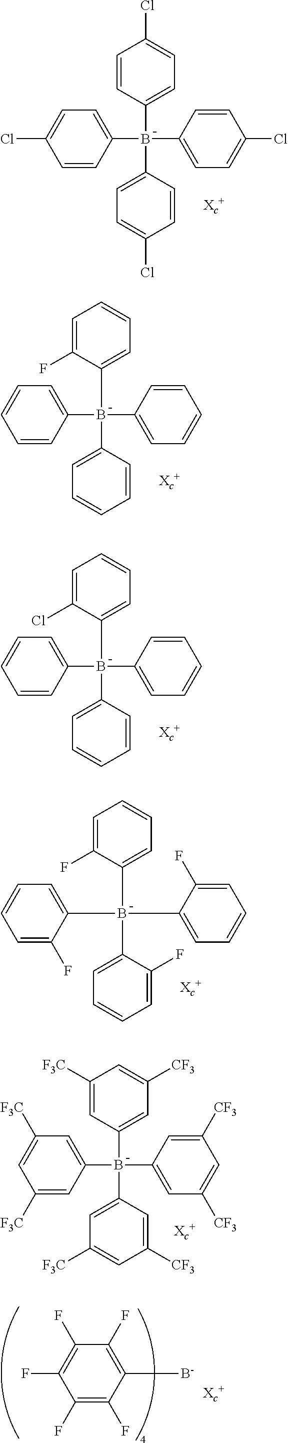

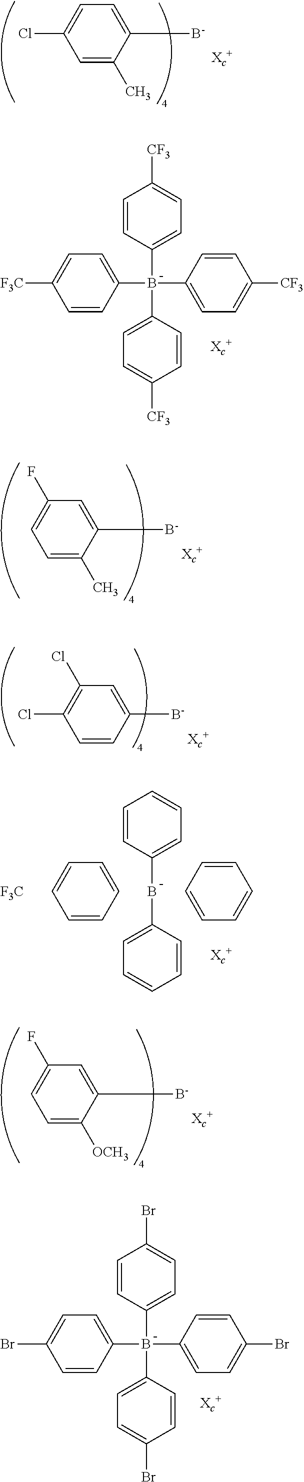

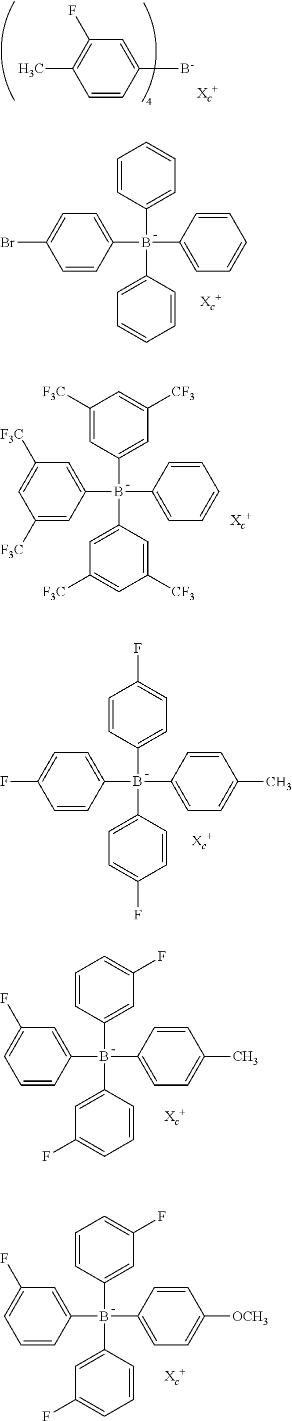

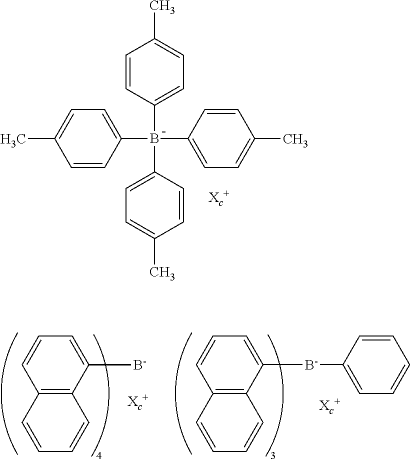

The electron-donating polymerization initiators may be used one kind alone or in combination of two or more kinds.

The content of the electron-donating polymerization initiator is preferably from 0.01 to 30% by weight, more preferably from 0.05 to 235% by weight, and still more preferably from 0.1 to 20% by weight based on the total solid content of the image-recording layer.

### <Infrared Absorbing Agent>

The infrared absorbing agent has a function of being excited by infrared ray and transferring electron and/or energy to a polymerization initiator or the like. Further, it has a function of converting the infrared ray absorbed into heat. The infrared absorbing agent preferably has a maximum absorption in a wavelength range from 750 to 1,400 nm. The infrared absorbing agent includes a dye and a pigment, and the dye is preferably used.

As the dye, commercially available dyes and known dyes described in documents, for example, “Dye Handbook” (edited by the Society for Synthetic Organic Chemistry, published in 1970) can be used. Specific examples thereof include dyes, for example, an azo dye, a metal complex azo dye, a pyrazolone azo dye, a naphthoquinone dye, an anthraquinone dye, a phthalocyanine dye, a carbonium dye, a quinoneimine dye, a methine dye, a cyanine dye, a squarylium dye, a pyrylium salt, and a metal thiolate complex.

Of the dyes, a cyanine dye, a squarylium dye and a pyrylium salt are preferred, a cyanine dye is more preferred, and an indolenine cyanine dye is particularly preferred.

The cyanine dye includes a cyanine dye represented by formula (a) shown below.

formula (a)

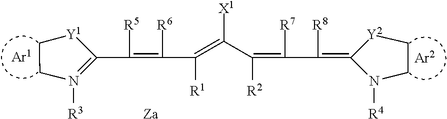

In formula (a), X¹ represents a hydrogen atom, a halogen atom, —N(R⁹)(R¹⁰), —X-L¹ or a group shown below. R⁹ and R¹⁰, which may be the same or different, each represents an aromatic hydrocarbon group having from 6 to 10 carbon atoms, an alkyl group having from 1 to 8 carbon atoms or a hydrogen atom, or R⁹ and R¹⁰ may be combined with each other to from a ring. The aromatic hydrocarbon group having from 6 to 10 carbon atoms or the alkyl group having from 1 to 8 carbon atoms may have a substituent. R⁹ and R¹⁰ preferably represent phenyl groups, respectively. X² represents an oxygen atom or a sulfur atom, and L¹ represents a hydrocarbon group having from 1 to 12 carbon atoms or a hydrocarbon group having from 1 to 12 carbon atoms and containing a hetero atom. Here, the hetero atom represents a nitrogen atom, a sulfur atom, an oxygen atom, a halogen atom or a selenium atom. In the formula shown below, Xa⁻ has the same meaning as Za⁻ defined hereinafter, and R^{a} represents a hydrogen atom or a substituent selected from an alkyl group, an aryl group, a substituted or unsubstituted amino group and a halogen atom.

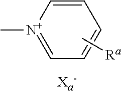

In formula (a), R¹ and R² each independently represents a hydrocarbon group having from 1 to 12 carbon atoms. In view of the preservation stability of the coating solution for the image-recording layer, it is preferred that R¹ and R² each represents a hydrocarbon group having two or more carbon atoms. Further, it is particularly preferred that R¹ and R² are combined with each other to form a 5-membered ring or a 6-membered ring.

In formula (a), Ar¹ and Ar², which may be the same or different, each represents an aromatic hydrocarbon group. The aromatic hydrocarbon group may have a substituent. Preferred examples of the aromatic hydrocarbon group include a benzene ring group and a naphthalene ring group. Preferred examples of the substituent include a hydrocarbon group having 12 or less carbon atoms, a halogen atom and an alkoxy group having 12 or less carbon atoms. Y¹ and Y², which may be the same or different, each represents a sulfur atom or a dialkylmethylene group having 12 or less carbon atoms. R³ and R⁴, which may be the same or different, each represents a hydrocarbon group having 20 or less carbon atoms. The hydrocarbon group having 20 or less carbon atoms may have a substituent. Preferred examples of the substituent include an alkoxy group having 12 or less carbon atoms, a carboxyl group and a sulfo group. R⁵, R⁶, R⁷ and R⁸, which may be the same or different, each represents a hydrogen atom or a hydrocarbon group having 12 or less carbon atoms. In view of the availability of raw materials, a hydrogen atom is preferred. Za⁻ represents a counter anion. However, Za⁻ is not necessary when the cyanine dye represented by formula (a) has an anionic substituent in the structure thereof and neutralization of charge is not needed. Za⁻ is preferably a halide ion, a perchlorate ion, a tetrafluoroborate ion, a hexafluorophosphate ion or a sulfonate ion, and more preferably a perchlorate ion, a hexafluorophosphate ion or an arylsulfonate ion in view of the preservation stability of the coating solution for the image-recording layer.

In the cyanine dye represented by formula (a), X¹ is more preferably a diphenylamino group. Further, it is more preferred that X¹ is a diphenylamino group, and Y¹ and Y² are both dimethylmethylene groups.

Specific examples of the cyanine dye include compounds described in paragraphs 0017 to 0019 of JP-A-2001-133969, paragraphs 0016 to 0021 of JP-A-2002-023360 and paragraphs 0012 to 0037 of JP-A-2002-040638, preferably compounds described in paragraphs 0034 to 0041 of JP-A-2002-278057 and paragraphs 0080 to 0086 of JP-A-2008-195018, particularly preferably compound described in paragraphs 0035 to 0043 of JP-A-2007-90850

Further, compounds described in paragraphs 0008 to 0009 of JP-A-5-5005 and paragraphs 0022 to 0025 of JP-A-2001-222101 can also be preferably used.

As the pigment, compounds described in paragraphs 0072 to 0076 of JP-A-2008-195018 are preferred.

The infrared absorbing agents may be used one kind alone or in combination of two or more kinds.

The content of the infrared absorbing agent is preferably from 0.05 to 30% by weight, more preferably from 0.1 to 20% by weight, and particularly preferably from 0.2 to 10% by weight, based on the total solid content of the image-recording layer.

### <Polymerizable Compound>

The polymerizable compound may be, for example, a radical polymerizable compound or a cationic polymerizable compound, and is preferably an addition polymerizable compound having at least one ethylenically unsaturated bond (ethylenically unsaturated compound). The ethylenically unsaturated compound is preferably a compound having at least one terminal ethylenically unsaturated bond, and more preferably a compound having two or more terminal ethylenically unsaturated bonds. The polymerizable compound may have a chemical form, for example, a monomer, a prepolymer, that is, a dimer, a trimer or an oligomer, or a mixture thereof.

Examples of the monomer include an unsaturated carboxylic acid (for example, acrylic acid, methacrylic acid, itaconic acid, crotonic acid, isocrotonic acid or maleic acid) and an ester or amide thereof. Preferably, an ester of an unsaturated carboxylic acid with a polyhydric alcohol compound and an amide of an unsaturated carboxylic acid with a polyvalent amine compound are used. An addition reaction product of an unsaturated carboxylic acid ester or amide having a nucleophilic substituent, for example, a hydroxy group, an amino group or a mercapto group, with a monofunctional or polyfunctional isocyanate or an epoxy compound, or a dehydration condensation reaction product of the unsaturated carboxylic acid ester or amide with a monofunctional or polyfunctional carboxylic acid is also suitably used. Further, an addition reaction product of an unsaturated carboxylic acid ester or amide having an electrophilic substituent, for example, an isocyanate group or an epoxy group with a monofunctional or polyfunctional alcohol, amine or thiol, or a substitution reaction product of an unsaturated carboxylic acid ester or amide having a leaving substituent, for example, a halogen atom or a tosyloxy group with a monofunctional or polyfunctional alcohol, amine or thiol is also suitably used. In addition, compounds in which the unsaturated carboxylic acid described above is replaced by an unsaturated phosphonic acid, styrene, vinyl ether or the like can also be used. These compounds are described, for example, in JP-T-2006-508380, JP-A-2002-287344, JP-A-2008-256850, JP-A-2001-342222, JP-A-9-179296, JP-A-9-179297, JP-A-9-179298, JP-A-2004-294935, JP-A-2006-243493, JP-A-2002-275129, JP-A-2003-64130, JP-A-2003-280187 and JP-A-10-333321.

Specific examples of the monomer which is an ester of a polyhydric alcohol compound with an unsaturated carboxylic acid include, as an acrylic acid ester, for example, ethylene glycol diacrylate, 1,3-butanediol diacrylate, tetramethylene glycol diacrylate, propylene glycol diacrylate, trimethylolpropane triacrylate, hexanediol diacrylate, tetraethylene glycol diacrylate, pentaerythritol tetraacrylate, sorbitol triacrylate, isocyanuric acid ethylene oxide (EO) modified triacrylate and polyester acrylate oligomer, and as a methacrylic acid ester, for example, tetramethylene glycol dimethacrylate, neopentyl glycol dimethacrylate, trimethylolpropane trimethacrylate, ethylene glycol dimethacrylate, pentaerythritol trimethacrylate, bis[p-(3-methacryloxy-2-hydroxypropoxy)phenyl]dimethylmethane and bis[p-(methacryloxyethoxy)phenyl]dimethylmethane. Specific examples of the monomer which is an amide of a polyvalent amine compound with an unsaturated carboxylic acid include methylene bisacrylamide, methylene bismethacrylamide, 1,6-hexamethylene bisacrylamide, 1,6-hexamethylene bismethacrylamide, diethylenetriamine trisacrylamide, xylylene bisacrylamide and xylylene bismethacrylamide.

Urethane type addition-polymerizable compounds produced using an addition reaction between an isocyanate and a hydroxy group are also suitably used and specific examples thereof include vinylurethane compounds having two or more polymerizable vinyl groups per molecule obtained by adding a vinyl monomer containing a hydroxy group represented by formula (M) shown below to a polyisocyanate compound having two or more isocyanate groups per molecule, described in JP-B-48-41708.

CH₂═C(R^{M4})COOCH₂CH(R^{M5})OH (M)

In formula (M), R^{M4} and R^{M5} each independently represents a hydrogen atom or a methyl group.

Further, urethane acrylates described in JP-A-51-37193, JP-B-2-32293, JP-B-2-16765, JP-A-2003-344997 and JP-A-2006-65210, urethane compounds having an ethylene oxide skeleton described in JP-B-58-49860, JP-B-56-17654, JP-B-62-39417, JP-B-62-39418, JP-A-2000-250211 and JP-A-2007-94138, and urethane compounds having a hydrophilic group described in U.S. Pat. No. 7,153,632, JP-T-8-505958, JP-A-2007-293221 and JP-A-2007-293223 are suitably used.

Details of the method of using the polymerizable compound, for example, selection of the structure, individual or combination use or an amount added, can be appropriately determined in consideration of the final use of the lithographic printing plate precursor.

The content of the polymerizable compound is preferably from 1 to 50% by weight, more preferably from 3 to 30% by weight, and still more preferably from 5 to 20% by weight based on the total solid content of the image-recording layer.

The image-recording layer can contain a binder polymer, a chain transfer agent, a low molecular weight hydrophilic compound, an oil-sensitizing agent, and other components.

### <Binder Polymer>

The binder polymer is preferably a polymer having a film-forming property, and preferably includes, for example, a (meth)acrylic resin, a polyvinyl acetal resin and a polyurethane resin.

The binder polymer for use in the image-recording layer of the on-press development type lithographic printing plate precursor (hereinafter also referred to as binder polymer for on-press development) will be described in detail.

The binder polymer for on-press development is preferably a binder polymer having an alkylene oxide chain. The binder polymer having an alkylene oxide chain may have a poly(alkylene oxide) moiety in a main chain or a side chain. Further, it may be a graft polymer having poly(alkylene oxide) in a side chain or a block copolymer of a block composed of repeating units containing poly(alkylene oxide) and a block composed of repeating units not containing (alkylene oxide).

In the case where the binder polymer has the poly(alkylene oxide) moiety in the main chain, a polyurethane resin is preferred. A polymer of the main chain in the case where the poly (alkylene oxide) moiety included in the side chain includes a (meth)acrylic resin, a polyvinyl acetal resin, a polyurethane resin, a polyurea resin, a polyimide resin, a polyamide resin, an epoxy resin, a polystyrene resin, a novolak type phenol resin, a polyester resin, synthetic rubber and natural rubber, and the (meth) acrylic resin is particularly preferred.

The alkylene oxide is preferably an alkylene oxide having from 2 to 6 carbon atoms, and particularly preferably an ethylene oxide or a propylene oxide.

The number of repetition of the alkylene oxides in the poly(alkylene oxide) moiety is preferably from 2 to 120, more preferably from 2 to 70, and still more preferably from 2 to 50.

It is preferred that the number of repetition of the alkylene oxides is 120 or less, because degradations of the printing durability due to both abrasion and decrease in ink-receiving property are prevented.

The poly(alkylene oxide) moiety is preferably included in a structure represented by formula (AO) shown below as the side chain of the binder polymer, and more preferably included in the structure represented by formula (AO) shown below as the side chain of the (meth)acrylic resin.

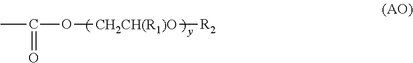

In formula (AO), y represents 2 to 120, R₁ represents a hydrogen atom or an alkyl group, and R, represents a hydrogen atom or a monovalent organic group.

The monovalent organic group is preferably an alkyl group having from 1 to 6 carbon atoms. Specific examples thereof include a methyl group, an ethyl group, an n-propyl group, an isopropyl group, an n-butyl group, a sec-butyl group, an isobutyl group, a tert-butyl group, an n-pentyl group, an isopentyl group, a neopentyl group, an n-hexyl group, an isohexyl group, 1,1-dimethylbutyl group, 2,2-dimethylbutyl group, a cyclopentyl group and a cyclohexyl group.

In formula (AO), y is preferably 2 to 70 and more preferably 2 to 50. R₁ is preferably a hydrogen atom or a methyl group and particularly preferably a hydrogen atom. R₂ is particularly preferably a hydrogen atom or a methyl group.

The binder polymer may have a crosslinking property in order to improve the film strength of the image area. In order to impart the crosslinking property to the binder polymer, a crosslinkable functional group, for example, an ethylenically unsaturated bond is introduced into a main chain or side chain of the polymer. The crosslinkable functional group may be introduced by copolymerization or may be introduced by a polymer reaction.

Examples of the polymer having an ethylenically unsaturated bond in the main chain of the molecule include poly-1.4-butadiene and poly-1,4-isoprene.

Examples of the polymer having an ethylenically unsaturated bond in the side chains of the molecule include polymers of esters or amides of acrylic acid or methacrylic acid in which the ester or the amide residue (R of —COOR or —CONHR) has an ethylenically unsaturated bond.

Examples of the residue (R described above) having an ethylenically unsaturated bond include —(CH₂)ₙCR^{1A}═CR^{2A}R^{3A}, —(CH₂O)ₙCH₂CR^{1A}═CR^{2A}R^{3A}, —(CH₂CH₂O)ₙCH₂CR^{1A}═CR^{2A}R^{3A}, —(CH₂)ₙNH—CO—O—CH₂CR^{1A}═CR^{2A}R^{3A}, —(CH₂)ₙ—O—CO—CR^{1A}═CR^{2A}R^{3A} and —(CH₂CH₂O)₂—X^{A} (in the formulae, each of R^{A1} to R^{A3} independently represents a hydrogen atom, a halogen atom, an alkyl group having from 1 to 20 carbon atoms, an aryl group, an alkoxy group or an aryloxy group, or R^{A1} and R^{A2} or R^{A3} may be combined with each other to form a ring. n represents an integer of 1 to 10. X^{A} represents a dicyclopentadienyl residue.).

Specific examples of the ester residue include —CH₂CH═CH₂, —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂ and —CH₂CH₂O—X (in the formula, X represents a dicyclopentadienyl residue.).

Specific examples of the amide residue include —CH₂CH═CH₂, —CH₂CH₂—Y (in the formula, Y represents a cyclohexene residue) and —CH₂CH₂—OCO—CH═CH₂.

The binder polymer having a crosslinking property is cured as described below. For example, a free radical (a polymerization initiation radical or a growing radical in the polymerization process of a polymerizable compound) is added to the crosslinkable functional group thereof and is addition-polymerized between the polymers directly or through a polymerization chain of the polymerizable compound, thereby forming crosslinkage between the polymer molecules. Alternatively, an atom in the polymer (for example, a hydrogen atom on carbon atom adjacent to the crosslinkable functional group) is drawn off by a free radical to from a polymer radical, and the polymer radicals are bonded to each other, thereby forming crosslinkage between the polymer molecules to be cured.

The content of the crosslinkable group in the binder polymer (content of unsaturated double bond which can be radical-polymerized by iodimetry) is preferably from 0.1 to 10.0 mmol, more preferably from 1.0 to 7.0 mmol, and still more preferably from 2.0 to 5.5 mmol per gram of the binder polymer from the standpoint of a good sensitivity and good preservation stability.

Specific examples 1 to 11 of the binder polymer are shown below, but the invention is not limited thereto. In the following exemplary compounds, numeric values shown beside individual repeating units (numeric values shown beside main chain repeating waits) represent the molar percentages of the repeating units. The numeric value shown beside the repeating unit of a side chain represents the number of the repetition in the repeated portion. In addition, Me represents a methyl group, Et represents an ethyl group, and Ph represents a phenyl group.

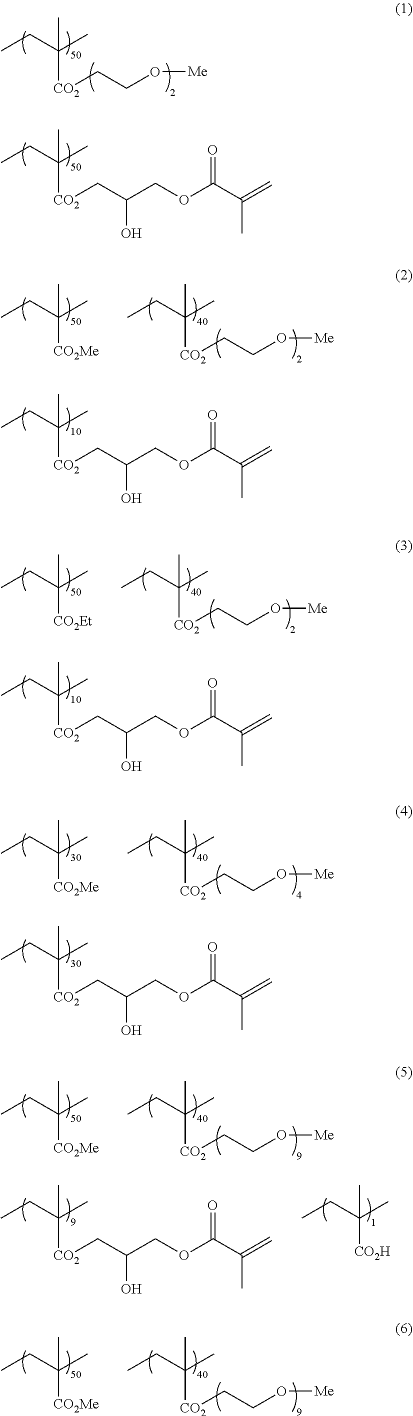

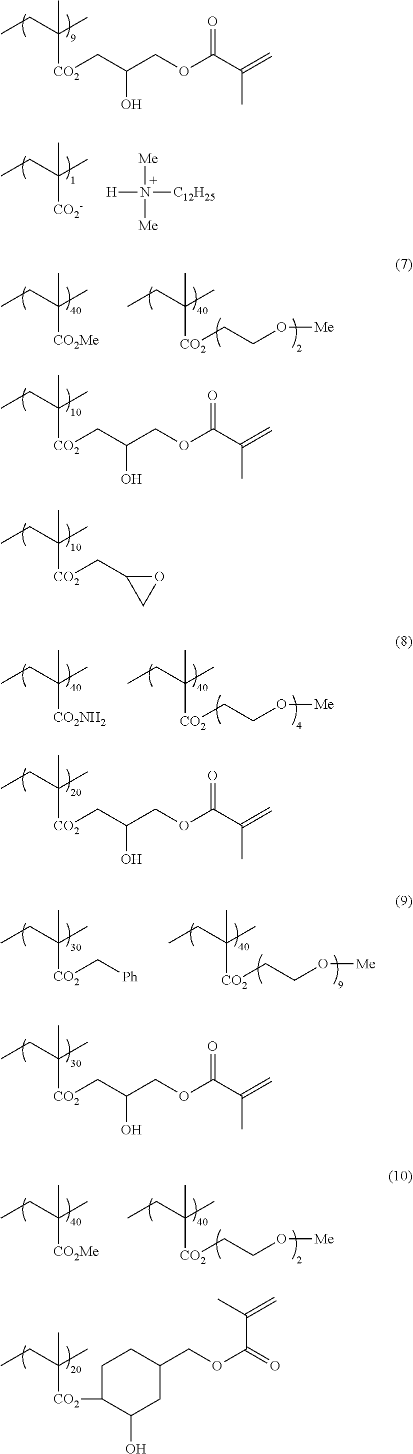

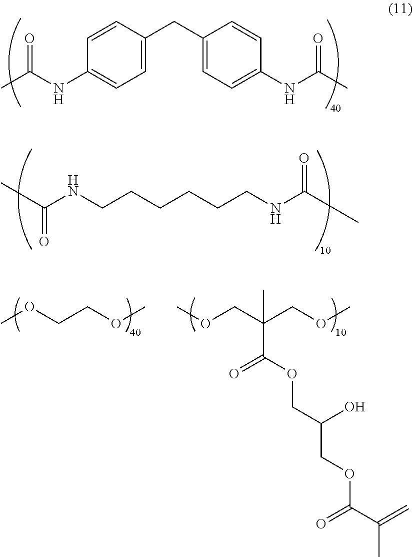

As to the molecular weight of the binder polymer, the weight average molecular weight (Mw) is 2,000 or more, preferably 5,000 or more, and more preferably 10,000 to 300,000, as a polystyrene equivalent value obtained by a GPC method.

If desired, a hydrophilic polymer, for example, polyacrylic acid or polyvinyl alcohol described in JP-A-2008-195018 can be used in combination. Further, a lipophilic polymer and a hydrophilic polymer can be used in combination.

The binder polymers may be used one kind alone or in combination of two or more kinds.

The content of the binder polymer is preferably from 1 to 90% by weight and more preferably from 5 to 80% by weight based on the total solid content of the image-recording layer.

### <Chain Transfer Agent>

The chain transfer agent contributes to improvement in the printing durability of a lithographic printing plate produced from the lithographic printing plate precursor.

The chain transfer agent is preferably a thiol compound, more preferably a thiol having 7 or more carbon atoms from the standpoint of the boiling point (difficulty of being volatilized), and still more preferably a compound having a mercapto group on an aromatic ring (aromatic thiol compound). The thiol compound is preferably a monofunctional thiol compound.

Specific examples of the chain transfer agent include the compounds shown below.

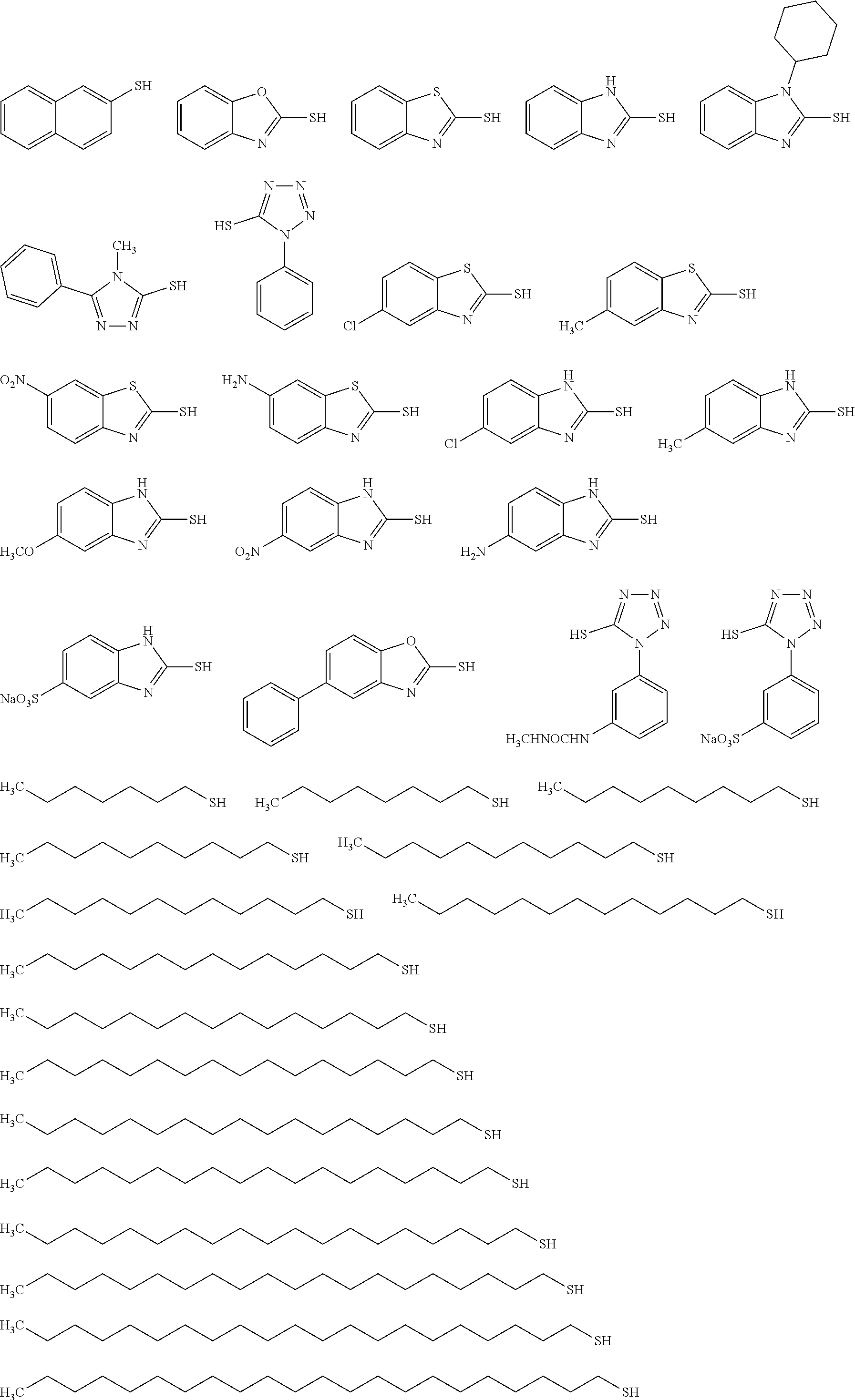

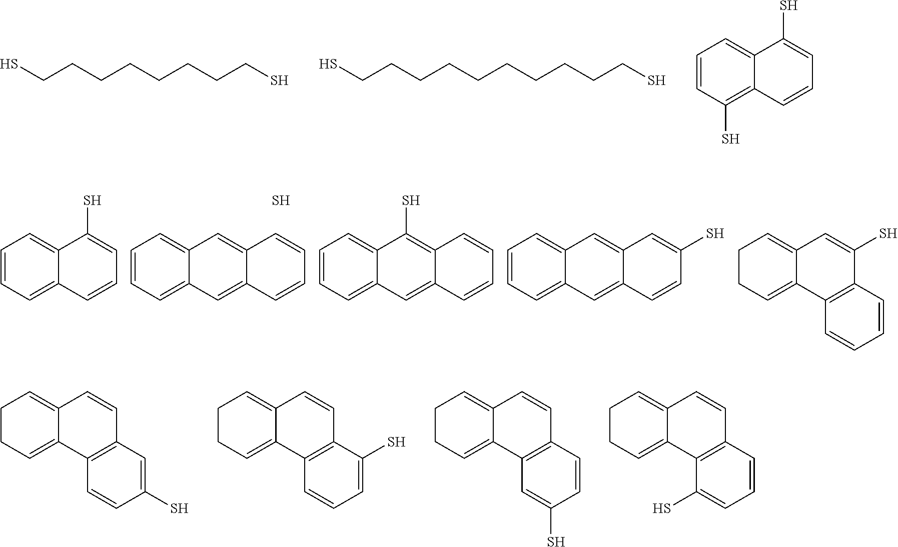

The chain transfer agents may be used one kind alone or in combination of two or more kinds.

The content of the chain transfer agent is preferably from 0.01 to 50% by weight, more preferably from 0.05 to 40% by weight, and still more preferably from 0.1 to 30% by weight based on the total solid content of the image-recording layer.

### <Low Molecular Weight Hydrophilic Compound>

The low molecular weight hydrophilic compound contributes to improvement in the on-press development property of the lithographic printing plate precursor without deteriorating the printing durability of a lithographic printing plate produced from the lithographic printing plate precursor. The low molecular weight hydrophilic compound is preferably a compound having a molecular weight of less than 1,000, more preferably a compound having a molecular weight of less than 800, and still more preferably a compound having a molecular weight of less than 500.

The low molecular weight hydrophilic compound includes, for example, a water-soluble organic compound including, for example, a glycol, for example, ethylene glycol, diethylene glycol, triethylene glycol, propylene glycol, dipropylene glycol or tripropylene glycol and an ether or ester derivative thereof, a polyol, for example, glycerol, pentaerythritol or tris(2-hydroxyethyl) isocyanurate, an organic amine, for example, triethanolamine, diethanolamine or monoethanolamine and a salt thereof, an organic sulfonic acid, for example, an alkylsulfonic acid, toluenesulfonic acid or benzenesulfonic acid and a salt thereof, an organic sulfamic acid, for example, an alkylsulfamic acid and a salt thereof, an organic sulfuric acid, for example, an alkylsulfuric acid or an alkylethersulfuric acid and a salt thereof, an organic phosphonic acid, for example, phenylphosphonic acid and a salt thereof, an organic carboxylic acid, for example, tartaric acid, oxalic acid, citric acid, malic acid, lactic acid, gluconic acid or an amino acid and a salt thereof, and a betaine.

The low molecular weight hydrophilic compound preferably contains at least one selected from a polyol, an organic sulfate, an organic sulfonate and a betaine.

Specific examples of the organic sulfonate include an alkylsulfonate, for example, sodium n-butylsulfonate, sodium n-hexylsulfonate, sodium 2-ethylhexylsulfonate, sodium cyclohexylsulfonate, sodium n-octylsulfonate; an alkylsulfonate containing an ethylene oxide chain, for example, sodium 5,8,11-trioxapentadecane-1-sulfonate, sodium 5,8,11-trioxaheptadecane-1-sulfonate, sodium 13-ethyl-5,8,11-trioxaheptadecane-1-sulfonate or sodium 5,8,11,14-tetraoxatetracosane-1-sulfonate; an arylsulfonate, for example, sodium benzenesulfonate, sodium p-toluenesulfonate, sodium p-hydroxybenzenesulfonate, sodium p-styrenesulfonate, sodium isophthalic acid dimethyl-5-sulfonate, sodium 1-naphtylsulfonate, sodium 4-hydroxynaphtylsulfonate, disodium 1,5-naphthalenedisulfonate or trisodium 1,3,6-naphthalenetrisulfonate, and compounds described in paragraphs 0026 to 0031 of JP-A-2007-276454 and paragraphs 0020 to 0047 of JP-A-2009-154525. The salt may also be a potassium salt or a lithium salt.

The organic sulfate includes a sulfate of alkyl, alkenyl, alkynyl, aryl or heterocyclic monoether of polyethylene oxide. The number of ethylene oxide units is preferably from 1 to 4. The salt is preferably a sodium salt, a potassium salt or a lithium salt. Specific examples thereof include compounds described in paragraphs 0034 to 0038 of JP-A-2007-276454.

The betaine is preferably a compound in which a number of carbon atoms included in a hydrocarbon substituent on the nitrogen atom is from 1 to 5 is preferred. Specific examples thereof include trimethylammonium acetate, dimethylpropylammonium acetate, 3-hydroxy-4-trimethylammoniobutyrate, 4-(1-pyridinio)butyrate, 1-hydroxyethyl-1-imidazolioacetate, trimethylammonium methanesulfonate, dimethylpropylammonium methanesulfonate, 3-trimethylammonio-1-porpanesulfonate and 3-(1-pyridinio)-1-porpanesulfonate.

Since the low molecular weight hydrophilic compound has a small structure of hydrophobic portion and almost no surface active function, degradations of the hydrophobicity and film strength in the image area due to penetration of dampening water into the exposed area (image area) of the image-recording layer are prevented and thus, the ink receptive-property and printing durability of the image-recording layer can be preferably maintained.

The low molecular weight hydrophilic compounds may be used one kind alone or in combination of two or more kinds.

The content of the low molecular weight hydrophilic compound is preferably from 0.5 to 20% by weight, more preferably from 1 to 15% by weight, and still more preferably from 2 to 10% by weight based on the total solid content of the image-recording layer.

### <Oil-Sensitizing Agent>

The oil-sensitizing agent contributes to improvement in the ink receiving property (hereinafter, also simply referred to as “ink receptivity”) of a lithographic printing plate produced from the lithographic printing plate precursor. The oil-sensitizing agent includes, for example, a phosphonium compound, a nitrogen-containing low molecular weight compound and an ammonium group-containing polymer. In particular, in the case where the lithographic printing plate precursor contains an inorganic stratiform compound in its protective layer, the oil-sensitizing agent functions as a surface covering agent of the inorganic stratiform compound and prevents deterioration of the ink receptivity during printing due to the inorganic stratiform compound.

As the oil-sensitizing agent, it is preferred to use a phosphonium compound, a nitrogen-containing low molecular weight compound and an ammonium group-containing polymer in combination, and it is more preferred to use a phosphonium compound, a quaternary ammonium salt and an ammonium group-containing polymer in combination.

The phosphonium compound include phosphonium compounds described in JP-A-2006-297907 and JP-A-2007-50660. Specific examples thereof include tetrabutylphosphonium iodide, butyltriphenylphospsphonium bromide, tetraphenylphosphonium bromide, 1,4-bis(triphenylphosphonio)butane di(hexafluorophosphate), 1,7-bis(triphenylphosphonio)heptane sulfate, and 1,9-bis(triphenylphosphonio)nonane naphthalene-2,7-disulfonate.

The nitrogen-containing low molecular weight compound includes an amine salt and a quaternary ammonium salt, and also includes, an imidazolinium salt, a benzimidazolinium salt, a pyridinium salt and a quinolinium salt. Among these, the quaternary ammonium salt and the pyridinium salt are preferred. Specific examples thereof include tetramethylammonium hexafluorophosphate, tetrabutylammonium hexafluorophosphate, dodecyltrimethylammonium p-toluenesulfonate, benzyltriethylammonium hexafluorophosphate, benzyldimethyloctylammonium hexafluorophosphate, benzyldimethyldodecylammonium hexafluorophosphate and compounds described in paragraphs 0021 to 0037 of JP-A-2008-284858 and paragraphs 0030 to 0057 of JP-A-2009-90645.

The ammonium group-containing polymer may be any polymer containing an ammonium group in its structure and is preferably a polymer containing from 5 to 80% by mole of (meth)acrylate having an ammonium group in its side chain as a copolymerization component. Specific examples thereof include polymers described in paragraphs 0089 to 0105 of JP-A-2009-208458.

As to the ammonium group-containing polymer, its reduced specific viscosity value (unit: ml/g) determined according to the measuring method described in JP-A-2009-208458 is preferably in a rage from 5 to 120, more preferably in a rage from 10 to 110, particularly preferably in a rage from 15 to 100. When the reduced specific viscosity value described above is calculated in terms of a weight average molecular weight, from 10,000 to 150,000 is preferred, from 17,000 to 140,000 is more preferred, and 20,000 to 130,000 is particularly preferred.

Specific examples of the ammonium group-containing polymer are shown below.

(1) 2-(Trimethylammonio)ethyl methacrylate p-toluenesulfonate/3,6-dioxaheptyl methacrylate copolymer (molar ratio: 10/90, Mw: 45.000)
(2) 2-(Trimethylammonio)ethyl methacrylate hexafluorophosphate/3,6-dioxaheptyl methacrylate copolymer (molar ratio: 20/80, Mw: 60,000)
(3) 2-(Ethyldimethylammonio)ethyl methacrylate p-toluenesulfonate/hexyl methacrylate copolymer (molar ratio: 30/70, Mw: 45,000)
(4) 2-(Trimethylammonio)ethyl methacrylate hexafluorophosphate/2-ethylhexyl methacrylate copolymer (molar ratio: 20/80, Mw: 60,000)
(5) 2-(Trimethylammonio)ethyl methacrylate methylsulfate/hexyl methacrylate copolymer (molar ratio: 40/60, Mw: 70,000)
(6) 2-(Butyldimethylammonio)ethyl methacrylate hexafluorophosphate/3,6-dioxaheptyl methacrylate copolymer (molar ratio: 25/75, Mw: 65,000
(7) 2-(Butyldimethylammonio)ethyl acrylate hexafluorophosphate/3,6-dioxaheptyl methacrylate copolymer (molar ratio: 20/80, Mw: 65,000)
(8) 2-(Butyldimethylammonio)ethyl methacrylate 13-ethyl-5,8,11-trioxa-1-heptadecanesulfonate/3,6-dioxaheptyl methacrylate copolymer (molar ratio: 20/80, Mw: 75,000)
(9) 2-(Butyldimethylammonio)ethyl methacrylate hexafluorophosphate/3,6-dioxaheptyl methacrylate/2-hydroxy-3-methacryloyloxypropyl methacrylate copolymer (molar ratio: 15/80/5, Mw: 65,000)

The content of the oil-sensitizing agent is preferably from 0.01 to 30.0% by weight, more preferably from 0.1 to 15.0% by weight, and still more preferably from 1 to 10% by weight based on the total solid content of the image-recording layer.

### <Other Components>

The image-recording layer may contain other components, for example, a surfactant, a polymerization inhibitor, a higher fatty acid derivative, a plasticizer, inorganic particles or an inorganic stratiform compound. Specifically, respective components described in paragraphs 0114 to 0159 of JP-A-2008-284817 can be used.

According to one aspect of the image-recording layer, the image-recording layer contains an infrared absorbing agent, a polymerizable compound, a polymerization initiator, and at least one of a binder polymer and polymer particles. The image-recording layer preferably further contains a chain transfer agent.

According to another aspect of the image-recording layer, the image-recording layer contains an infrared absorbing agent, heat-fusible particles, and a binder polymer.

### <Formation of Image-Recording Layer>

The image-recording layer can be formed by appropriately dispersing or dissolving each of the necessary components described above in a known solvent to prepare a coating solution and coating the coating solution on a support by a known method, for example, bar coater coating and drying as described, for example, in paragraphs 0142 to 0143 of JP-A-2008-195018. The coating amount (solid content) of the image-recording layer after coating and drying may be varied according to the use, and is preferably from 0.3 to 3.0 g/m² from standpoint of obtaining good sensitivity and good film property of the image-recording layer.

The on-press development type lithographic printing plate precursor according to the invention may have an undercoat layer (sometimes also referred to as an intermediate layer) between the image-recording layer and the support, and a protective layer (sometimes also referred to as an overcoat layer) on the image-recording layer.

### [Undercoat Layer]

The undercoat layer strengthens adhesion between the support and the image-recording layer in the exposed area and makes removal of the image-recording layer from the support easy in the unexposed area, thereby contributing improvement in the developing property without accompanying degradation of the printing durability. In addition, in the case of infrared laser exposure, the undercoat layer functions as a heat insulating layer, and thus has an effect of preventing the heat generated by the exposure from diffusing to the support, thereby decreasing the sensitivity.

The compound used in the undercoat layer includes a polymer having an adsorbing group capable of adsorbing to the surface of the support and a hydrophilic group. In order to improve the adhesion property to the image-recording layer, a polymer having a crosslinkable group in addition to the adsorbing group and hydrophilic group is preferred. The compound used in the undercoat layer may be a low molecular compound or a polymer. The compounds used in the undercoat layer may be used in mixture of two or more thereof, if desired.

When the compound used in the undercoat layer is a polymer, a copolymer of a monomer having an adsorbing group, a monomer having a hydrophilic group and a monomer having a crosslinkable group is preferred.

The adsorbing group capable of adsorbing to the surface of the support is preferably a phenolic hydroxy group, a carboxyl group, —PO₃H₂—, —OPO₃H₂, —CONHSO₂—, —SO₂NHSO₂— or —COCH₂COCH₃. The hydrophilic group is preferably a sulfo group or a salt thereof or a salt of a carboxyl group. The crosslinkable group is preferably, for example, an acryl group, a methacryl group, an acrylamide group, a methacrylamide group or an allyl group.

The polymer may have a crosslinkable group introduced by a salt formation between a polar substituent of the polymer and a compound containing a substituent having a counter charge to the polar substituent of the polymer and an ethylenically unsaturated bond, and may also be further copolymerized with a monomer other than those described above, preferably a hydrophilic monomer.

Specifically, a silane coupling agent having an addition-polymerizable ethylenic double bond reactive group described in JP-A-10-282679 and a phosphorus compound having an ethylenic double bond reactive group described in JP-A-2-304441 are suitably used. Low molecular weight compounds or polymer compounds having a crosslinkable group (preferably an ethylenically unsaturated bond group), a functional group capable of interacting with the surface of the support and a hydrophilic group described in JP-A-2005-238816, JP-A-2005-125749, JP-A-2006-239867 and JP-A-2006-215263 are also preferably used.

Polymers having an adsorbing group capable of adsorbing to the surface of the support, a hydrophilic group and a crosslinkable group described in JP-A-2005-125749 and JP-A-2006-188038 are more preferred.

The content of the ethylenically unsaturated bond group in the polymer used in the undercoat layer is preferably from 0.1 to 10.0 mmol, and more preferably from 0.2 to 5.5 mmol per gram of the polymer.

The weight average molecular weight (Mw) of the polymer used in the undercoat layer is preferably 5,000 or more, and more preferably from 10,000 to 300,000.

The undercoat layer may contain a chelating agent, a secondary or tertiary amine, a polymerization inhibitor or a compound containing an amino group or a functional group having polymerization inhibition ability and a group capable of interacting with the surface of the support (for example, 1,4-diazabicyclo[2,2,2]octane (DABCO), 2,3,5,6-tetrahydroxy-p-quinone, chloranil, sulfophthalic acid, hydroxyethylethylenediaminetriacetic acid, dihydroxyethylethylenediaminediacetic acid or hydroxyethyliminodiacetic acid) in addition to the compound for the undercoat layer described above in order to prevent the occurrence of stain due to the preservation.

The undercoat layer is coated according to a known method. The coating amount (solid content) of the undercoat layer is preferably from 0.1 to 100 mg/m², and more preferably from 1 to 30 mg/m².

### [Protective Layer]

The protective layer has a function for preventing the occurrence of scratch in the image-recording layer or the ablation caused by exposure with a high illuminance laser beam, in addition to the function for suppressing the image formation inhibition reaction by blocking oxygen.

The protective layers having the characteristics described above are described, for example, in U.S. Pat. No. 3,458,311 and JP-B-55-49729. As the polymer of low oxygen permeability used in the protective layer, either a water-soluble polymer or a water-insoluble polymer can be appropriately selected and used, and two or more polymers can be mixed and used, if desired. Specific examples thereof include polyvinyl alcohol, modified polyvinyl alcohol, polyvinyl pyrrolidone, a water-soluble cellulose derivative and poly(meth)acrylonitrile.

As the modified polyvinyl alcohol, acid-modified polyvinyl alcohol having a carboxyl group or a sulfo group is preferably used. Specific examples thereof include modified polyvinyl alcohols described in JP-A-2005-250216 and JP-A-2006-259137.

The protective layer preferably contains an inorganic stratiform compound in order to enhance the oxygen-blocking property. The inorganic stratiform compound is a particle having a thin tabular shape and includes, for instance, mica, for example, natural mica or synthetic mica, talc represented by the following formula: 3MgO.4SiO.H₂O, taeniolite, montmorillonite, saponite, hectorite and zirconium phosphate.

The inorganic stratiform compound preferably used is a mica compound. The mica compound includes mica, for example, natural mica represented by the following formula: A (B, C)₂₋₅D₄O₁₀(OH, F, O)₂, (wherein A represents any of K, Na and Ca, B and C each represents any of Fe(II), Fe(III), Mn, Al, Mg and V, and D represents Si or Al) or synthetic mica.

Of the mica, examples of the natural mica include muscovite, paragonite, phlogopite, biotite and lepidolite. Examples of the synthetic mica include non-swellable mica, for example, fluorophlogopite KMg₃(AlSi₃O₁₀)F₂ or potassium tetrasilicic mica KMg_{2.5}(Si₄O₁₀)F₂, and swellable mica, for example, Na tetrasilicic mica NaMg_{2.5}(Si₄O₁₀)F₂, Na or Li taeniolite (Na, Li)Mg₂Li(Si₄O₁₀)F₂, or montmorillonite-based Na or Li hectorite (Na, Li)_{1/8}Mg_{2/5}Li_{1/8}(Si₄O₁₀)F₂. Synthetic smectite is also useful.

Among the mica compounds, fluorine-based swellable mica is particularly useful. That is, the swellable synthetic mica has a laminate structure composed of a unit crystal lattice layer having a thickness of approximately from 10 to 15 angstroms, and metallic atom substitution in the lattices thereof is remarkably large in comparison with other clay minerals. As a result, lack of positive charge occurs in the lattice layers and to compensate the lack, a cation, for example, Li⁺, Na⁺, Ca²⁺ or Mg²⁺ is adsorbed between the lattice layers. The cation interposed between the layers is referred to as an exchangeable cation and is able to exchange with various cations. Particularly, in the case where the cation between the layers is Li⁺ or Na⁺, the ionic radius is small, and thus the bond between layered crystal lattices is weak, and mica is significantly swollen by water. When the swellable synthetic mica is shared, the mica is easily cleaved to form sol which is stable in water. This tendency is strong in the swellable synthetic mica so that the swellable synthetic mica is particularly preferably used.

With respect to the shape of the mica compound, the thinner the thickness or the larger the plain size as long as smoothness of coated surface and transmission of active ray are not impaired, the better from the standpoint of diffusion control. Therefore, the aspect ratio is preferably 20 or more, more preferably 100 or more, and particularly preferably 200 or more. The aspect ratio is the ratio of the long diameter to the thickness of a particle and can be measured from projection view obtained from the microphotograph of the particle. As the aspect ratio increases, the effect obtained becomes larger.

As to the particle diameter of the mica compound, the average long diameter thereof is preferably from 0.3 to 20 μm, more preferably from 0.5 to 10 μm, and particularly preferably from 1 to 5 μm. The average thickness of the particles is preferably 0.1 μm or less, more preferably 0.05 μm or less, and particularly preferably 0.01 μm or less. Specifically, for example, in the case of swellable synthetic mica which is a typical compound, a preferred aspect has a thickness of approximately from 1 to 50 nm and a surface size (long diameter) of approximately from 1 to 20 μm.

The content of the inorganic stratiform compound is preferably from 0 to 60% by weight, and more preferably from 3 to 50% by weight based on the total solid content of the protective layer. Even in the case where plural kinds of inorganic stratiform compounds are used in combination, the total amount of the inorganic stratified compounds is preferably the content described above. Within the range described above, the oxygen-blocking property is improved, and good sensitivity can be obtained. In addition, the degradation of the ink-receiving property can be prevented.

The protective layer may contain known additives, for example, a plasticizer for imparting flexibility, a surfactant for improving a coating property, or inorganic fine particles for controlling a sliding property on the surface. Further, the oil-sensitizing agent described in the image-recording layer may be added to the protective layer.

The protective layer is coated using a known coating method. The coating amount (solid content) of the protective layer is preferably from 0.01 to 10 g/m², more preferably from 0.02 to 3 g/m², and particularly preferably from 0.02 to 1 g/m².

The on-press development type lithographic printing plate precursor according to the invention has a shear droop shape in which an amount X of shear droop is from 25 to 150 μm and a width Y of shear droop is from 70 to 300 μm at the edge portion thereof.

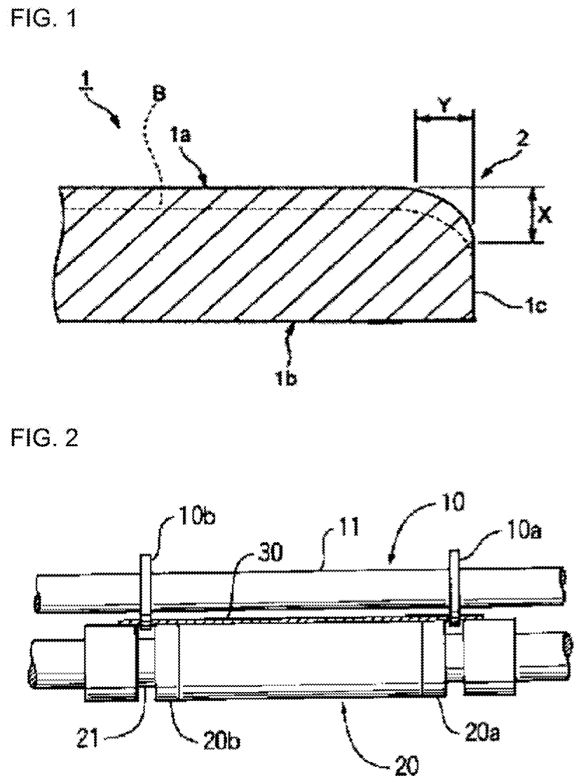

FIG. 1 is a schematic view illustrating a cross-sectional shape of an edge portion of a lithographic printing plate precursor.

In FIG. 1, a lithographic printing plate precursor 1 has a shear droop 2 at the edge portion thereof. A distance X between the upper end (boundary point between the shear droop 2 and an edge surface 1c) of the edge surface 1c of the lithographic printing plate precursor 1 and the extension line of an image-recording layer surface (a protective layer surface in the case where the protective layer is formed) 1a is referred to as an “amount of shear droop” and a distance Y between the starting point of the shear droop of the image recording layer surface 1a of the lithographic printing plate precursor 1 and the extension line of the edge surface 1c is referred to as a “width of shear droop”.

The amount of shear droop of the edge portion is preferably 35 μm or more and more preferably 40 μm or more. The upper limit of the amount of shear droop is preferably 150 μm from the standpoint of preventing degradation of the on-press development property caused by deterioration in the surface state of the edge portion. When the on-press development property is degraded, ink adheres to the remaining image-recording layer to cause edge stain. When the amount of shear droop is less than 25 μm, ink adhered to the edge portion is easily transferred to a blanket to cause edge stain in some cases. In the case where the amount of shear droop is in the range of 25 to 150 μm, when the width of shear droop is small, the occurrence of cracks in the edge portion increases so that printing ink is accumulated in the cracks to cause edge stain. From these viewpoints, the width of shear droop is suitably in the range of 70 to 300 μm and preferably in the range of 80 to 250 μm. The ranges of the amount of shear droop and the width of shear droop described above are not relevant to the edge shape of a support surface 1b of the lithographic printing plate precursor 1.

Similar to the image-recording layer surface 1a, the shear droop is usually generated in a boundary B between the image-recording layer and the support, and the support surface 1b in the edge portion of the lithographic printing plate precursor 1.

The formation of the edge portion having the shear droop shape described above can be performed, for example, by adjusting the conditions of cutting the lithographic printing plate precursor.

Specifically, the formation of the edge portion can be performed by adjusting a gap between an upper cutting blade and a lower cutting blade, an amount of biting, a blade angle, and the like in a slitter device used at the time of cutting the lithographic printing plate precursor.

For example, FIG. 2 is a conceptual view illustrating an example of a cutting portion of a slitter device. A pair of upper and lower cutting blades 10 and 20 are disposed on right and left sides in the slitter device. The cutting blades 10 and 20 are respectively formed of a disc-shaped round blade, and upper cutting blades 10a and 10b are coaxially supported by a rotary shaft 11 and lower cutting blades 20a and 20b are coaxially supported by a rotary shaft 21. The upper cutting blades 10a and 10b and the lower cutting blades 20a and 20b are rotated in directions opposite to each other. A lithographic printing plate precursor 30 is cut in a predetermined width by being passed through the gap between the upper cutting blades 10a and 10b and the lower cutting blades 20a and 20b. An edge portion having the shear droop shape can be formed by adjusting the gap between the upper cutting blade 10a and the lower cutting blade 20a and the gap between the upper cutting blade 10b and the lower cutting blade 20b of the cutting unit of the slitter device.

In the on-press development type lithographic printing plate precursor according to the invention, an area ratio of cracks present on a surface of the anodized film in a region corresponding to the width Y of shear droop is 30% or less.

Here, the region corresponding to the width Y of shear droop means a region from a point at the intersection of the extension line of an image-recording layer surface (a protective layer surface in the case where the protective layer is formed) 1a and the extension line of the edge surface 1c in FIG. to the place where the extension line of 1a comes into contact with the image-recording layer surface (the protective layer surface in the case where the protective layer is formed).

The area ratio of cracks present on a surface of the anodized film is calculated by the method described below.

The constituting layers (undercoat layer, image-recording layer, protective layer) of the lithographic printing plate precursor are removed using Plasma Reactor PR300 manufactured by Yamato Scientific Co., Ltd. An exposed surface of the anodized film of the aluminum support is subjected to a conductive treatment by vapor-depositing a Pt—Pd film by 3 nm to prepare a sample. The sample is observed using a field emission scanning electron microscope (FE-SEM) (S-4800 manufactured by Hitachi High-Technologies Corp.) at an accelerating voltage of 30 kV. A continuous photograph from the edge portion to the central portion at observation magnification of 1.500 times is taken and an image of 150×50 μm is obtained. The image is subjected to extraction of the crack shape using the luminance difference between the crack portion and the surface of the anodized film and binarization treatment by an image processing software “ImageJ”, thereby calculating a ratio of cracks in the range of 150×50 μm to determine the area ratio of cracks.

The area ratio of cracks is more preferably 10% or less and particularly preferably 6% or less from the standpoint of preventing the occurrence of edge stain.

An average width of cracks present on a surface of the anodized film in the region corresponding to the width Y of shear droop is also a factor involved in the occurrence of edge stain. The average width of cracks present on a surface of the anodized film is preferably 20 μm or less.

The average width of cracks present on a surface of the anodized film is calculated by the method described below.

An image of 150×50 μm is obtained in the same manner as the method for calculating the area ratio of cracks present on a surface of the anodized film described above. The image is subjected to extraction of the crack shape using the luminance difference between the crack portion and the surface of the anodized film and binarization treatment by an image processing software “ImageJ”, widths of 15 cracks in the range of 150×50 μm are measured and the average value thereof is taken as the average width of the cracks.

In order to adjust the area ratio of cracks present on a surface of the anodized film in the region corresponding to the width Y of shear droop to 30% or less and/or adjust the average width of cracks present on a surface of the anodized film in the region corresponding to the width Y of shear droop to 20 μm or less, it is preferred to control the amount of the anodized film described above in the range of 0.5 to 5.0 g/m². The amount of the anodized film is more preferably controlled in the range of 0.8 to 1.2 g/m² from the standpoint of preventing the occurrence of edge stain.

The amount of the anodized film is calculated by the method described below.

The constituting layers (undercoat layer, image-recording layer, protective layer) of the lithographic printing plate precursor are removed using Plasma Reactor PR300 manufactured by Yamato Scientific Co., Ltd. An exposed surface of the anodized film of the aluminum support is measured by an X-ray fluorescence spectrometer (ZSX Primus II manufactured by Rigaku Corp.), and the amount (g/m²) of the anodized film is calculated using a calibration curve separately prepared. The calibration curve is prepared based on the relationship between the Compton scattered radiation intensity obtained from the X-ray fluorescence spectrometer and the amount of the anodized film calculated by the Mason method. In order to increase the measurement accuracy of the Mason method, the Mason solutions used are new solutions. Conditions for the X-ray fluorescence spectrometry are described below. X-ray tube: Rh, measurement spectrum: RhLα, tube voltage: 50 kV, tube current: 60 mA, slit: S2, dispersive crystal: Ge, detector: PC, analysis area: 30 mmϕ, peak position (2θ): 89.510 deg., background (2θ): 87.000 deg, and 92.000 deg., and integration time: 60 seconds/sample.

In order to control the amount of the anodized film, for example, a method of adjusting the electrolysis time in the anodizing treatment is used.

It is preferred that the amount of the anodized film in the region corresponding to the width Y of shear droop of the lithographic printing plate precursor is smaller than the amount of the anodized film in a region other than the region corresponding to the width Y of shear droop of the lithographic printing plate precursor. When the amount of the anodized film is decreased, the anodized film may be damaged during handling and printing of the lithographic printing plate precursor and as a result, scratches may occur. Therefore, the occurrence of scratches can be suppressed by decreasing the amount of the anodized film only at the edge portion involved in the edge stain.

In order to adjust the area ratio of cracks present on a surface of the anodized film in the region corresponding to the width Y of shear droop to 30% or less and/or adjust the average width of cracks present on a surface of the anodized film in the region corresponding to the width Y of shear droop to 20 μm or less, it is preferred to control the average diameter of the micropores present on a surface of the anodized film in the range of 5 to 100 μm. The average diameter of the micropores is more preferably controlled in the range of 5 to 35 nm.

The average diameter of the micropores of the anodized film is calculated by the method described below.

The constituting layers (undercoat layer, image-recording layer, protective layer) of the lithographic printing plate precursor are removed using Plasma Reactor PR 300 manufactured by Yamato Scientific Co., Ltd. An exposed surface of the anodized film of the aluminum support is subjected to a conductive treatment by vapor-depositing a carbon or Pt—Pd film by 3 nm to prepare a sample. As to the sample, continuous photographs from the edge portion to the central portion at observation magnification of 150,000 times are taken using a field emission scanning electron microscope (FE-SEM) (S-4800 manufactured by Hitachi High-Technologies Corp.) and four images of 400 μm×600 μm are obtained. The diameters of 90 micropores present in the four images are measured and averaged to determine the average diameter of the micropores. When the shape of the micropore is not circular, a circle having a projected area same as the projected area of the micropore is assumed, and the diameter of the circle is taken as the diameter of the micropore.

In the case where the micropore has a large-diameter portion and a small-diameter portion, a surface of the large-diameter portion and a surface of the small-diameter portion are observed by N=4 sheets using FN-SEM at magnification of 150,000 times. In the images of the four sheets obtained, the diameters of the micropores (of large-diameter portion and small-diameter portion) present in the range of 400×600 nm were measured and averaged. When the depth of the large-diameter portion is deep and it is difficult to measure the diameter of the small-diameter portion, the upper part of the anodized film is cut and thereafter various diameters are determined.

The depth of the micropores in the anodized film is a value determined by observing the cross section of the support (anodized film) using FE-SEM (large-diameter portion depth observation: 150,000 times, small-diameter portion depth observation: 50,000 times), and in the images obtained, measuring the depth of 25 arbitrary micropores and averaging.

In order to control the average diameter of the micropores of the anodized film, for example, a method of adjusting the treatment time in the pore-widening treatment is used.

The on-press development type lithographic printing plate precursor according to the invention has a feature in that the occurrence of edge stain can be prevented without decreasing performances, for example, on-press development property by having the shear droop shape in which an amount X of shear droop is from 25 to 150 μm and a width Y of shear droop is from 70 to 300 μm provided at the edge portion thereof in combination with the area ratio of cracks present on a surface of the anodized film in the region corresponding to the width Y of shear droop is 30% or less. The feature described above cannot be achieved only by having the shear droop shape in which an amount X of shear droop is from 25 to 150 μm and a width Y of shear droop is from 70 to 300 μm provided at the edge portion thereof. Further, the feature described above cannot be achieved only by controlling the area ratio of cracks present on a surface of the anodized film in the region corresponding to the width Y of shear droop is 30% or less.

Moreover, the on-press development type lithographic printing plate precursor according to the invention has a feature in that the occurrence of edge stain can be prevented without performing a hydrophilizing treatment, for example, coating a coating solution containing a water-soluble compound on the edge region.

### [Method for Producing Lithographic Printing Plate]

The method for producing a lithographic printing plate according to the invention includes a step of imagewise exposing the lithographic printing plate precursor according to the invention (exposure step), and a step of removing an unexposed area of the image-recording layer of the lithographic printing plate precursor exposed image-wise with at least one of printing ink and dampening water on a printing press (on-press development step).

### (Exposure Step)

The image exposure is preferably performed using a method in which digital data are scanned and exposed using an infrared laser or the like.

The wavelength of the exposure light source is preferably in the range of 750 to 1,400 nm. The light source having a wavelength in the range of 750 to 1,400 nm is suitably a solid-state laser or semiconductor laser which radiates infrared rays. The exposure mechanism may be any of an internal drum system, an external drum system, a flat bed system, and the like.

The exposure step can be performed by a known method using a plate setter or the like. Alternatively, the exposure may be performed on a printing press equipped with an exposure device after the lithographic printing plate precursor is mounted on the printing press.

### (On-Press Development Step)

In the on-press development step, when printing is initiated by supplying printing ink and dampening water on a printing press without performing any development processing on the lithographic printing plate precursor after imagewise exposure, at the initial stage of printing, unexposed area of the lithographic printing plate precursor is removed and accordingly, the hydrophilic surface of the support is exposed to form a non-image area. As the printing ink and the dampening water, known printing ink and dampening water for lithographic printing are used. Any of printing ink and dampening water may be first supplied to the surface of the lithographic printing plate precursor, and it is preferred to first supply printing ink from the standpoint of preventing the dampening water from being contaminated by the components of the image-recording layer removed.

In the manner described above, the lithographic printing plate precursor is subjected to on-press development on an off-set printing press and is used as it is for printing a large number of sheets.

The method for producing a lithographic printing plate according to the present invention may also include other known steps in addition to the steps described above. Other steps include, for example, a plate inspection step of checking a position, a direction, or the like of a lithographic printing plate precursor before each step, and a checking step of checking a printed image after the on-press development step.

### EXAMPLE

Hereinafter, the invention will be described in detail with reference to the examples, but the invention is not limited thereto. With respect to the polymer compounds, unless otherwise particularly specified, the molecular weight is a weight average molecular weight (Mw) in terms of polystyrene determined by a gel permeation chromatography (GPC) method, and the ratio of repeating units is a molar percentage. Further, “parts” and “%” indicate “parts by weight” and “% by weight” unless otherwise specified.

### Examples 1 to 20 and Comparative Examples 1 to 2

### <Production of Support (1)>

An aluminum plate was subjected to treatments (a) to (g) described below in order to produce an aluminum support (Support (1)) having an anodized film. In addition, a water washing process was performed between all the treatment steps.

### (a) Alkali Etching Treatment

An aqueous solution having a sodium hydroxide concentration of 25% by weight, an aluminum ion concentration of 100 g/L and a temperature of 60° C. was sprayed from a spray tube to an aluminum plate (material: JIS 1050) having a thickness of 0.3 mm to perform the etching treatment. The etching amount of the surface of the aluminum plate to be subjected to an electrochemical roughening treatment was 3 g/m².

### (b) Desmut Treatment

An aqueous sulfuric acid solution (concentration: 300 g/L) having a temperature of 35° C. was sprayed from a spray tube to the aluminum plate for 5 seconds to perform the desmut treatment.

### (c) Electrochemical Roughening Treatment

The aluminum plate was continuously subjected to the electrochemical roughening treatment using an electrolytic solution (liquid temperature: 35° C.) prepared by dissolving aluminum chloride in a 1% by weight aqueous hydrochloric acid solution to set an aluminum ion concentration of 4.5 g/L, an AC power supply at 60 Hz, and a flat cell type electrolytic cell. A sinusoidal waveform was used in the AC power supply. In the electrochemical roughening treatment, the current density during the anode reaction of the aluminum plate at the peak of alternating current was 30 A/dm². The ratio of the total amount of electricity furnished for the anodic reaction on the aluminum alloy plate to the total amount of electricity furnished for the cathodic reaction thereon was 0.95. The amount of electricity was 480 C/dm² as the total amount of electricity when the aluminum alloy plate served as an anode. The electrolytic solution was circulated with a pump to agitate the inside of the electrolytic cell.

### (d) Alkali Etching Treatment

An aqueous solution having a sodium hydroxide concentration of 5% by weight, an aluminum ion concentration of 5 g/L and a temperature of 35° C. was sprayed from a spray tube to the aluminum plate to perform the etching treatment. The etching amount of the surface of the aluminum plate having been subjected to the electrochemical roughening treatment was 0.05 g/m².

### (e) Desmut Treatment

An aqueous solution having a sulfuric acid concentration of 300 g/L, an aluminum ion concentration of 5 g/L, and a temperature of 35° C. was sprayed from a spray tube to the aluminum plate for 5 seconds to perform the desmut treatment.

### (f) Anodizing Treatment

A direct current anodized film having a thickness of 1,000 nm was formed using an electrolytic solution of 15% by weight sulfuric acid (containing 0.5% by weight of aluminum ions) under the conditions of 40° C. and a current density of 15 A/dm². Then, water washing by spraying was performed.

### (g) Pore Widening Treatment

The aluminum plate was subjected to an alkali treatment using a 5% aqueous NaOH-solution at 30° C. for 2 seconds to produce Support (1).

### <Production of Support (2)>

Support (2) was produced in the same manner as in the production of Support (1) except that in the production of Support (1), (f) Anodizing treatment was changed to that described below and (g) Pore widening treatment was not performed.

### (f1) First Anodizing Treatment

A direct current anodized film was formed using an electrolytic solution of 15% by weight sulfuric acid (containing 0.5% by weight of aluminum ions) under the conditions of 60° C. and a current density of 30 A/dm². Then, water washing by spraying was performed.

### (f2) Second Anodizing Treatment

A direct current anodized film was formed using an electrolytic solution of 15% by weight sulfuric acid (containing 0.5% by weight of aluminum ions) under the conditions of 60° C. and a current density of 15 A/dm². Then, water washing by spraying was performed.

The thickness of the anodized film in Support (2) was 500 nm.

### <Production of Support (3)>

Support (3) was produced in the same manner as in the production of Support (2) except that in the production of Support (2), the treatment time of the second anodizing treatment was adjusted so as to form the anodized film having a thickness of 300 nm.

### <Production of Support (4)>

Support (4) was produced in the same manner as in the production of Support (1) except that in the production of Support (1), (g) Pore widening treatment was changed to that described below. The thickness of the anodized film in Support (4) was 1,000 nm.

### (g) Pore Widening Treatment

The aluminum plate was subjected to an alkali treatment using a 5% aqueous NaOH solution at 30° C. for 4 seconds.

### <Production of Support (5)>

Support (5) was produced in the same manner as in the production of Support (1) except that in the production of Support (1), (g) Pore widening treatment was changed to that described below. The thickness of the anodized film in Support (5) was 1,000 nm.

### (g) Pore Widening Treatment

The aluminum plate was subjected to an alkali treatment using a 5% aqueous NaOH solution at 30° C. for 6 seconds.

### <Production of Support (6)>

Support (6) was produced in the same manner as in the production of Support (1) except that in the production of Support (1), (g) Pore widening treatment was changed to that described below. The thickness of the anodized film in Support (6) was 1,000 rm.

### (g) Pore Widening Treatment

The aluminum plate was subjected to an alkali treatment using a 5% aqueous NaOH solution at 30° C. for 7 seconds.

### <Production of Support (7)>

Support (7) was produced in the same manner as in the production of Support (4) except that in the production of Support (4), the treatment time of the anodizing treatment was adjusted so as to form the anodized film having a thickness of 500 nm.

### <Production of Support (8)>

Support (8) was produced in the same manner as in the production of Support (6) except that in the production of Support (6), the treatment time of the anodizing treatment was adjusted so as to form the anodized film having a thickness of 300 nm.

### <Production of Support (9)>

Support (9) was produced in the same manner as in the production of Support (1) except that in the production of Support (1), (f) Anodizing treatment was changed to that described below. The thickness of the anodized film in Support (9) was 500 nm.

### (f) Anodizing Treatment

The anodizing treatment was performed using a 22% by weight aqueous phosphoric acid solution as an electrolytic solution under the conditions of 38° C. and a current density of 15 A/dm². Then, water washing by spraying was performed.

### <Production of Support (10)>

Support (10) was produced in the same manner as in the production of Support (5) except that in the production of Support (5), (g) Pore widening treatment was changed to that described below.

### (g) Pore Widening Treatment

Only the edge portion of aluminum plate was subjected to an alkali treatment using a 5% aqueous NaOH solution at 30° C. for 2 seconds. The thickness of the final anodized film in the shear droop portion was 1,000 nm.

### <Production of Supports (11) and (12)>

Supports (11) and (12) were produced in the same manner as in the production of Support (1) except that in the production of Support (1), (g) Pore widening treatment was not performed and the treatment time of the anodizing treatment was controlled so as to form the anodized film having a thickness described in Table 1, respectively.

### <Production of Support (13)>

Support (13) was produced in the same manner as in the production of Support (1) except that in the production of Support (1), (f) Anodizing treatment was changed to that described below and (g) Pore widening treatment was not performed.

### (f) Anodizing Treatment

The anodizing treatment was performed using a 15% by weight aqueous phosphoric acid solution as an electrolytic solution under the conditions of 35° C. and a current density of 4.5 A/dm². Then, water washing by spraying was performed. The thickness of the anodized film in Support (13) was 1,000 nm.

### <Production of Support (14)>

Support (14) was produced in the same manner as in the production of Support (13) except that in the production of Support (13), (f) Anodizing treatment was changed to that described below.

### (f1) First Anodizing Treatment

The first anodizing treatment was performed using a 15% by weight aqueous phosphoric acid solution as an electrolytic solution under the conditions of 35° C. and a current density of 4.5 A/dm². Then, water washing by spraying was performed. The amount of the first anodized film was 0.5 g/m².

### (12) Second Anodizing Treatment

The second anodizing treatment was performed using an aqueous sulfuric acid solution having a concentration of 170 g/L as an electrolytic solution under the conditions of 50° C. and a current density of 30 A/dm². Then, water washing by spraying was performed.

The thickness of the anodized film in Support (14) was 800 nm.

### <Production of Support (15)>

Support (15) was produced in the same manner as in the production of Support (13) except that in the production of Support (13), (f) Anodizing treatment was changed to that described below.

### (f1) First Anodizing Treatment

The first anodizing treatment was performed using a 15% by weight aqueous phosphoric acid solution as an electrolytic solution under the conditions of 35° C. and a current density of 4.5 A/dm². Then, water washing by spraying was performed. The amount of the first anodized film was set to 0.3 g/m² by adjusting the treatment time.

### (f1) Second Anodizing Treatment

The second anodizing treatment was performed using a 15% by weight aqueous phosphoric acid solution as an electrolytic solution under the conditions of 35° C. and a current density of 4.3 A/dm². Then, water washing by spraying was performed.

The thickness of the anodized film in Support (15) was 500 nm.

### <Production of Support (16)>

Support (16) was produced in the same manner as in the production of Support (1) except that in the production of Support (1), (f) Anodizing treatment and (g) Pore widening treatment were changed to those described below.

### (f1) First Anodizing Treatment

The first anodizing treatment was performed using a 15% by weight aqueous phosphoric acid solution as an electrolytic solution under the conditions of 35° C. and a current density of 4.5 A/dm². Then, water washing by spraying was performed. The amount of the first anodized film was 0.3 g/m².

### (g) Pore Widening Treatment

The aluminum plate was subjected to an alkali treatment using a 5% aqueous NaOH solution at 40° C. for 4 seconds. Then, water washing by spraying was performed.

### (f2) Second Anodizing Treatment

The second anodizing treatment was performed using an aqueous sulfuric acid solution having a concentration of 170 g/L as an electrolytic solution under the conditions of 50° C. and a current density of 13 A/dm². Then, water washing by spraying was performed.

The thickness of the anodized film in Support (16) was 1,000 nm. The micropores of the anodized film in Support (16) were configured from a large-diameter portion and a small-diameter portion, and the depth of the large-diameter portion, the average diameter of the large-diameter portion, the depth of the small-diameter portion and the average diameter of the small-diameter portion at the communication part were 100 nm, 100 nm, 900 nm and 8 nm, respectively.

### <Production of Support (17)>

Support (17) was produced in the same manner as in the production of Support (1) except that in the production of Support (1), (f) Anodizing treatment and (g) Pore widening treatment were changed to those described below.

### (f1) First Anodizing Treatment

The first anodizing treatment was performed using an aqueous sulfuric acid solution having a concentration of 170 g/L as an electrolytic solution under the conditions of 50° C. and a current density of 30 A/dm². Then, water washing by spraying was performed. The amount of the first anodized film was 0.5 g/m².

### (g) Pore Widening Treatment

The aluminum plate was subjected to an alkali treatment using a 5% aqueous NaOH solution at 40° C. for 3 seconds. Then, water washing by spraying was performed.

### (f5) Second Anodizing Treatment

The second anodizing treatment was performed using an aqueous sulfuric acid solution having a concentration of 170 g/L as an electrolytic solution under the conditions of 50° C. and a current density of 30 A/dm². Then, water washing by spraying was performed.

The thickness of the anodized film in Support (17) was 1,000 nm. The micropores of the anodized film in Support (17) were configured from a large-diameter portion and a small-diameter portion, and the depth of the large-diameter portion, the average diameter of the large-diameter portion, the depth of the small-diameter portion and the average diameter of the small-diameter portion at the communication part were 100 nm, 30 nm, 900 nm and 10 nm, respectively.

### <Formation of Undercoat Layer>

Coating solution (1) for undercoat layer having the composition shown below was coated on the support by a bar and dried in an oven at 100° C. for 30 seconds to form an undercoat layer having a dry coating amount of 20 mg/m².

(Coating solution (1) for undercoat layer)

| | | |
|---|---|---|
| Compound (1) for undercoat layer (shown below) | 0.18 | parts |
| Methanol | 55.24 | parts |
| Distilled water | 6.15 | parts |

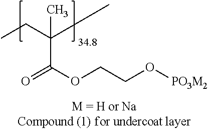

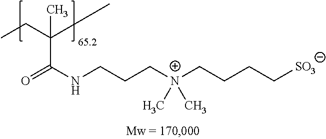

### <Formation of Image-Recording Layer (1)>

Coating solution (1) for image-recording layer having the composition shown below was coated on the undercoat layer by a bar and dried in an oven at 100° C. for 60 seconds to form Image-recording layer (1) having a dry coating amount of 1.0 g/m².

Coating solution (1) for image-recording layer was prepared by mixing Photosensitive solution (1) shown below with Microgel solution shown below just before the coating, followed by stirring.

<Photosensitive solution (1)>

| | |
|---|---|
| Binder polymer (1) having structure shown below | 0.240 g |
| Polymerization initiator (1) having structure shown below | 0.245 g |
| Infrared absorbing agent (1) having structure shown below | 0.046 g |
| Borate compound | 0.010 g |
| TPB having structure shown below | |
| Polymerizable compound | 0.192 g |
| Tris(acryloyloxyethyl) isocyanurate (NK ESTER A-9300, | |
| manufactured by Shin-Nakamura Chemical Co., Ltd.) | |
| Low molecular weight hydrophilic compound | 0.062 g |
| Tris(2-hydroxyethyl) isocyanurate | |
| Low molecular weight hydrophilic compound (1) having | 0.050 g |
| structure shown below | |
| Oil-sensitizing agent | 0.055 g |
| Phosphonium compound (1) having structure shown below | |
| Oil-sensitizing agent | 0.018 g |
| Benzyl dimethyl octyl ammonium PF₆ salt | |
| Oil-sensitizing agent | 0.035 g |
| Ammonium group-containing polymer (1) having structure | |
| shown below (reduced specific viscosity: 44 ml/g) | |
| Fluorine-based surfactant (1) having structure shown below | 0.008 g |
| 2-Butanone | 1.091 g |
| 1-Methoxy-2-propanol | 8.609 g |

<Microgel solution>

| | |
|---|---|
| Microgel (1) | 2.640 g |
| Distilled water | 2.425 g |

The structures of Binder polymer (1). Polymerization initiator (1), Infrared absorbing agent (1), TBP, Low molecular weight hydrophilic compound (1), Phosphonium compound (1), Ammonium group-containing polymer (1) and Fluorine-based surfactant (1) described above are shown below.

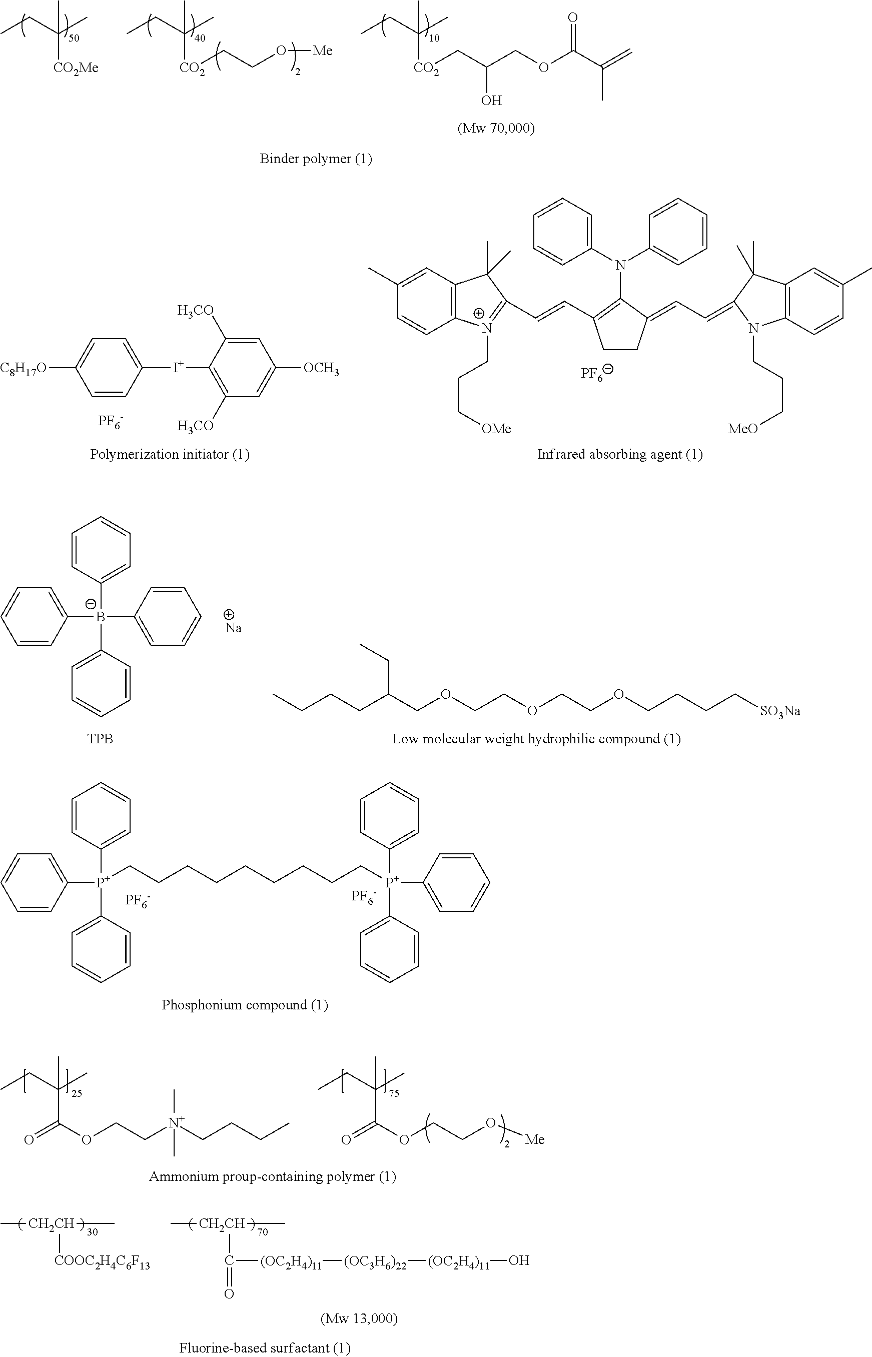

A method for preparing Microgel (1) used for the microgel solution is described below.

### <Preparation of Polyvalent Isocyanate Compound (1)>

To a suspension solution containing 17.78 g (80 mmol) of isophorone diisocyanate, 7.35 g (20 mmol) of Polyhydric phenol compound (1) described below and 25.31 g of ethyl acetate was added 43 mg of bismuth tris(2-ethylhexanoate) (NEOSTAN U-600 manufactured by Nitto Kasei Co., Ltd.), followed by stirring. After the generation of heat had ended, the reaction temperature was set to 50° C., and the mixture was stirred for 3 hours to obtain an ethyl acetate solution (50% by weight) of Polyvalent isocyanate compound (1).

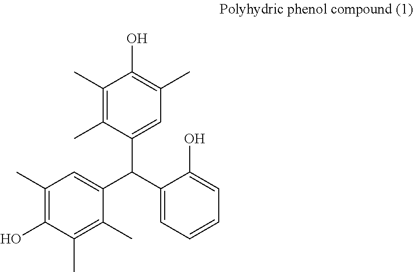 [SMILES: Cc1cc(C(c2ccccc2O)c2cc(C)c(O)c(C)c2C)c(C)c(C)c1O]

### <Preparation of Microgel (1)>

The oil phase component and aqueous phase component described below were mixed and the mixture was emulsified at 12,000 rpm for 10 minutes using a homogenizer. The resulting emulsion was stirred at 45° C. for 4 hours, 5.20 g of a 10% by weight aqueous solution of 1,8-diazabicyclo[5.4.0]undec-7-ene-octanoic acid salt (U-CAT SA102, manufactured by San-Apro Co., Ltd.) was added thereto, and the mixture was stirred at room temperature for 30 minutes and allowed to stand at 45° C. for 24 hours. The solid concentration was adjusted to 20% by weight using distilled water to obtain an aqueous dispersion liquid of Microgel (1). The average particle diameter was measured using a light scattering method and found to be 0.28 μm.

### (Oil Phase Component)

(Component 1) Ethyl acetate: 12.0 g
Component 2) An adduct obtained by adding trimethylolpropane (6 mol) to xylylene diisocyanate (18 mol) and further adding thereto methyl terminal polyoxyethylene (1 mol, a number of repetitions of oxyethylene unit: 90) (a 50% by weight ethyl acetate solution, manufactured by Mitsui Chemicals Inc.): 3.76 g
(Component 3) Polyvalent isocyanate compound (1) (as a 50% by weight ethyl acetate solution): 15.0 g
(Component 4) A 65% by weight ethyl acetate solution of dipentaerythritol pentaacrylate (SR-399, manufactured by Sartomer Co.): 11.54 g
(Component 5) A 10% by weight ethyl acetate solution of a sulfonate type surfactant (PIONINE A-41-C, manufactured by Takemoto Oil & Fat Co., Ltd.): 4.42 g

### (Aqueous Phase Component)

Distilled water: 46.87 g

### <Formation of Image-Recording Layer (2)>

Coating solution (2) for image-recording layer having the composition shown below was coated on the undercoat layer by a bar and dried in an oven at 94° C. for (60 seconds to form Image-recording layer (2) having a dry coating amount of 0.85 g/m².

(Coating solution (2) for image-recording layer)

| | |
|---|---|
| Polymerizable compound 1 *¹ | 0.325 parts |
| Graft copolymer 1 *² | 0.060 parts |
| Graft copolymer 2 *³ | 0.198 parts |
| Mercapto-3-triazole *⁴ | 0.180 parts |
| Irgacure 250 *⁵ | 0.032 parts |
| Infrared absorbing agent 1 (shown below) | 0.007 parts |
| Sodium tetraphenylborate (shown below) | 0.04 parts |
| Klucel 99M *⁶ | 0.007 parts |
| Byk 336 *⁷ | 0.015 parts |
| n-Propanol | 7.470 parts |
| Water | 1.868 parts |

*¹ Polymerizable compound 1 is dipentaerythritol hexaacrylate (manufactured by Shin-Nakamura Chemical Co., Ltd.).
*² Graft copolymer 1 is a polymer grafted with poly(oxy-1,2-ethanediyl), α-(2-methyl-1-oxo-2-propenyl-ω-methoxy-, ethenylbenzene as a 25% dispersion in a solvent of 80% n-propanol/20% water.
*³ Graft copolymer 2 is polymer particles of a graft copolymer of poly(ethylene glycol) methyl ether methacrylate/styrene/acrylonitrile = 10/9/81 as a 24% dispersion in a solvent of 80% n-propanol/20% water. A volume average particle diameter of the polymer particles is 193 nm.
*⁴ Mercapto-3-triazole is 3-mercapto-1H, 2,4-triazole available from PCAS (France).
*⁵ Irgacure 250 is a 75% propylene carbonate solution of iodonium (4-methylphenyl)[4-(2-methylpropyl)phenyl]hexafluorophosphate available from Ciba Specialty Chemicals Inc.
*⁶ Klucel 99M is a 1% aqueous solution of a hydroxypropyl cellulose thickener available from Hercules Inc.
*⁷ Byk 336 is a 25% xylene/methoxypropyl acetate solution of a modified dimethylpolysiloxane copolymer available from Byk Chemie.

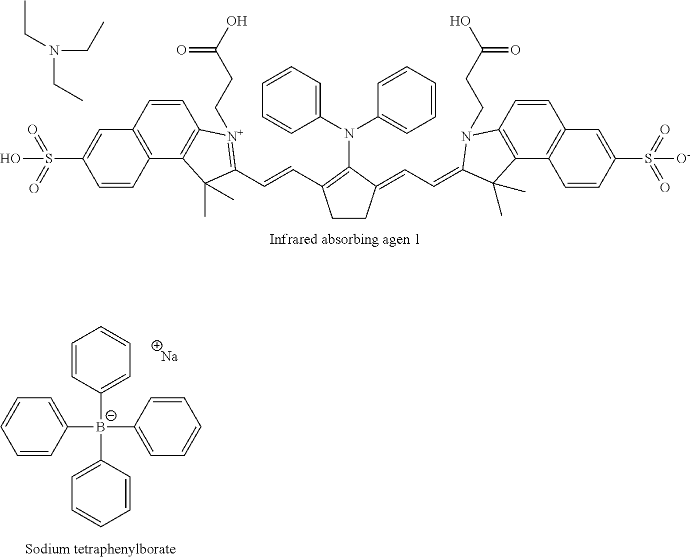

### <Formation of Protective Layer>

Coating solution for protective layer having the composition shown below was coated on the image-recording layer by a bar and dried in an oven at 120° C. for 60 seconds to form a protective layer having a dry coating amount of 0.15 g/m², thereby producing a lithographic printing plate precursor.

<Coating solution for protective layer>

| | |
|---|---|
| Dispersion of inorganic stratiform compound (1) | 1.5 g |
| show below | |
| Aqueous 6% by weight solution of polyvinyl alcohol | 0.55 g |
| (CKS 50, sulfonic acid-modified, saponification degree: | |
| 99% by mole or more, polymerization degree: 300, | |
| manufactured by Nippon Synthetic Chemical Industry | |
| Co., Ltd.) | |
| Aqueous 6% by weight solution of polyvinyl alcohol | 0.03 g |
| (PVA-405, saponification degree: 81.5% by mole, | |
| polymerization degree: 500, manufactured by Kuraray | |
| Co., Ltd.) | |
| Aqueous 1% by weight solution of surfactant | 0.86 g |
| (polyoxyethylene lauryl ethers, EMALEX 710, | |
| manufactured by Nihon Emulsion Co., Ltd.) | |
| Ion-exchanged water | 6.0 g |

A method for preparing Dispersion of inorganic stratiform compound (1) used in the coating solution for protective layer is described below.

### <Preparation of Dispersion of Inorganic Stratiform Compound (1)>

To 193.6 g of ion-exchanged water was added 6.4 g of synthetic mica (Somasif ME-100, manufactured by CO-OP Chemical Co., Ltd.) and the mixture was dispersed using a homogenizer until an average particle diameter (according to a laser scattering method) reached 3 μm. The aspect ratio of the resulting dispersed particles was 100 or more.

### (Production of Lithographic Printing Plate Precursor)

Lithographic printing plate precursors were produced by combining the support and image-recording layer described above as shown in Table 1. Although the protective layer described above was formed on Image-recording layer (1), any protective layer was not formed on Image-recording layer (2).

### (Cutting of Lithographic Printing Plate Precursor)

The lithographic printing plate precursor was cut using a rotary blade as shown in FIG. 2 while adjusting the gap between the upper cutting blade and the lower cutting blade, the amount of biting and the blade angle, whereby a shear droop shape having an amount of shear droop and a width of shear droop as shown in Table 1 was formed at the edge portion.

### (Evaluations of Lithographic Printing Plate Precursor)

### <Edge Stain Preventing Property>

The lithographic printing plate precursor was exposed using a LUXEL PLATESETTER T-6000III, equipped with an infrared semiconductor laser, manufactured by Fujifilm Corp. under conditions of an external drum rotation speed of 1,000 rpm, a laser output of 70%, and a resolution of 2,400 dpi. The exposed image included a solid image and a 50% halftone dot chart.

The image-exposed lithographic printing plate precursor was mounted on an offset rotary printing press manufactured by Tokyo Kikai Seisakusho, Ltd. Using Soiby KKST-S (Red) manufactured by Inktec Co., Ltd., as newspaper printing ink and Toyo ALKY manufactured by Toyo Ink Co., Ltd., as dampening water, printing was performed at a printing rate of 100,000 sheets/hour with a double water scale of the water scale to eliminate background stains. A 1,000th printed material was sampled and the degree of stains at the edge portion was evaluated according to the criteria shown below.

5: Not stained at all
4: Intermediate level between 5 and 3
3: Slightly stained but acceptable level
2: Intermediate level between 3 and 1 (acceptable level)
1: Clearly stained and unacceptable level

### <On-Press Development Property>

The lithographic printing plate precursor image-exposed in the same manner as in the evaluation of the edge stain preventing property described above was mounted on an offset rotary printing press manufactured by Tokyo Kikai Seisakusho, Ltd. Using Soiby KKST-S (Red) manufactured by Inktec Co., Ltd., as newspaper printing ink and Eco Seven N-1 manufactured by Sakata Inx Co., Ltd., as dampening water, printing was performed at a printing rate of 100,000 W sheets/hour on paper for newspaper. The number of papers for newspaper required until the on-press development of the unexposed area of the-recording layer on the printing press was completed and no ink was transferred to the non-image area was measured as the number for on-press development and evaluated according to the criteria shown below.

5: Number for on-press development is 25 sheets or less.
4: Number for on-press development is from 26 to 30 sheets.
3: Number for on-press development is from 31 to 35 sheets.
2: Number for on-press development is from 36 to 40 sheets.
1: Number for on-press development is 100 sheets or more and unacceptable level.

### <Scratch Stain Preventing Property>

The lithographic printing plate precursor was conditioned in an environment of 25° C. and 60% RH for 2 hours, then a piece of 2.5 cm×2.5 cm was punched out from the lithographic printing plate precursor, set on a continuous loading scratching intensity tester TYPE-18 manufactured by Shinto Scientific Co., Ltd. in such a manner that the back side of the piece of the lithographic printing plate precursor which had been punched was brought into contact with a surface of the lithographic printing plate precursor which had not been punched, and several sites of the lithographic printing plate precursor was scratched while applying a load of 0 to 1,500 gf. The lithographic printing plate precursor thus-scratched was exposed using a LUXEL PLATESETTER T-6000III, equipped with an infrared semiconductor laser, manufactured by Fujifilm Corp. under conditions of an external drum rotation speed of 1,000 rpm, a laser output of 70%, and a resolution of 2,400 dpi.

The image-exposed lithographic printing plate precursor was mounted on an offset rotary printing press manufactured by Tokyo Kikai Seisakusho, Ltd. Using Soiby KKST-S (Red) manufactured by Inktec Co., Ltd., as newspaper printing ink and Eco Seven N-1 manufactured by Sakata Inx Co., Ltd., as dampening water, printing was performed at a printing rate of 100,000 sheets/hour on paper for newspaper. In the printing process, a 1,000th printed material was sampled and the degree of scratch stains caused by the scratches was visually observed and evaluated according to the criteria shown below.

3: Scratch stains cannot be confirmed with visual recognition and using a 6 magnification loupe.
2: Scratch stains cannot be confirmed with visual recognition but scratch stains which are able to be confirmed using a 6 magnification loupe are found at several sites.
1: Scratch stains which are able to be confirmed with visual recognition are found at multiple sites and unacceptable level.

The evaluation results are shown in Table 1. In Table 1, the area ratio of cracks, the average width of cracks, the amount of the anodized film and the average diameter of micropores were calculated according to the methods described above.

TABLE 1

| | | | Thickness | Amount | Width | | | | | | | |
|---|---|---|---|---|---|---|---|---|---|---|---|---|
| | | | of | of | of | | Average | Amount of | Average | | | Scratch |
| | | Image- | Anodized | Shear | Shear | | Width of | Anodized | Diameter of | Edge Stain | On-Press | Stain |
| | | Recoding | Film | Droop | Droop | Area Ratio | Cracks | Film | Micropores | Preventing | Development | Preventing |
| | Support | Layer | (nm) | (μm) | (μm) | of Cracks | (μm) | (g/m²) | (nm) | Property | Property | Property |
| Example 1 | (1) | (1) | 1,000 | 30 | 90 | 6% | 5 | 2.1 | 15 | 5 | 4 | 3 |
| Example 2 | (1) | (1) | 1,000 | 50 | 150 | 12% | 10 | 2.1 | 15 | 3 | 4 | 3 |
| Example 3 | (1) | (1) | 1,000 | 80 | 240 | 20% | 16 | 2.1 | 15 | 2 | 4 | 3 |
| Example 4 | (2) | (1) | 500 | 50 | 150 | 6% | 5 | 1.2 | 12 | 5 | 5 | 3 |
| Example 5 | (3) | (1) | 300 | 50 | 150 | 4% | 3 | 0.7 | 12 | 5 | 5 | 2 |
| Example 6 | (4) | (1) | 1,000 | 50 | 150 | 10% | 8 | 2.0 | 20 | 4 | 4 | 3 |
| Example 7 | (5) | (1) | 1,000 | 50 | 150 | 6% | 5 | 1.9 | 30 | 5 | 3 | 3 |
| Example 8 | (6) | (1) | 1,000 | 50 | 150 | 6% | 5 | 1.8 | 35 | 5 | 2 | 3 |
| Example 9 | (7) | (1) | 500 | 50 | 150 | 4% | 3 | 0.9 | 20 | 5 | 4 | 3 |
| Example 10 | (7) | (1) | 500 | 80 | 150 | 12% | 10 | 0.9 | 20 | 3 | 4 | 3 |
| Example 11 | (8) | (1) | 300 | 50 | 150 | 1% | 1 | 0.2 | 35 | 5 | 2 | 2 |
| Example 12 | (2) | (2) | 500 | 50 | 150 | 6% | 5 | 1.2 | 11 | 5 | 5 | 3 |
| Example 13 | (9) | (2) | 500 | 50 | 150 | 6% | 5 | 0.7 | 35 | 5 | 5 | 3 |
| Example 14 | (10) | (1) | 1,000 | 50 | 150 | 6% | 5 | 2.2 | 30 | 5 | 5 | 3 |
| Example 15 | (13) | (1) | 1,000 | 50 | 150 | 6% | 5 | 1.7 | 40 | 5 | 2 | 3 |
| Example 16 | (13) | (2) | 1,000 | 50 | 150 | 6% | 5 | 1.7 | 40 | 5 | 2 | 3 |
| Example 17 | (14) | (2) | 800 | 50 | 150 | 6% | 5 | 1.2 | 40 | 5 | 2 | 3 |
| Example 18 | (15) | (2) | 500 | 50 | 150 | 6% | 4 | 0.6 | 40 | 5 | 2 | 3 |
| Example 19 | (16) | (2) | 1,000 | 50 | 150 | 3% | 2 | 1.0 | 100/8 *1 | 5 | 2 | 3 |
| Example 20 | (17) | (1) | 1,000 | 50 | 150 | 6% | 5 | 1.9 | 30/10 *2 | 5 | 3 | 3 |
| Comparative | (11) | (1) | 1,000 | 120 | 360 | 36% | 29 | 2.3 | 8 | 1 | 5 | 3 |
| Example 1 | | | | | | | | | | | | |
| Comparative | (12) | (1) | 1,500 | 120 | 360 | 38% | 30 | 3.3 | 8 | 1 | 5 | 3 |
| Example 2 | | | | | | | | | | | | |

*1: It indicates that the average diameter of the large-diameter portion and the average diameter of the small-diameter portion at the communication part are 100 nm and 8 nm, respectively.
*2: It indicates that the average diameter of the large-diameter portion and the average diameter of the small-diameter portion at the communication part are 30 nm and 10 nm, respectively.

From the results shown in Table 1, it can be seen that the lithographic printing plate precursor according to the invention is prevented from the edge stain without decreasing performances, for example, on-press development property and scratch stain preventing property. On the contrary, it can be seen that the edge stain occurs in the lithographic printing plate precursor in the comparative examples.

Further, in the lithographic printing plate precursor according to the invention, the degradation of image-forming performance in the region of edge portion is not recognized.

According to the present invention, an on-press development type lithographic printing plate precursor in which edge stain is prevented without decreasing performances, for example, on-press development property and scratch stain preventing property and a method for producing a lithographic printing plate using the on-press development type lithographic printing plate precursor can be provided.

While the invention has been described in detail and with reference to specific embodiments thereof, it will be apparent to those skilled in the art that various changes and modifications can be made therein without departing from the spirit and scope of the invention.

### REFERENCE SIGNS LIST

1: Lithographic printing plate precursor
1a: Image-recording layer surface
1b: Support surface
1c: Edge surface
2: Shear droop
X: Amount of shear droop
Y: Width of share droop
B: Boundary between image recording layer and support
10: Cutting blade
10a: Upper cutting blade
10b: Upper cutting blade
11: Rotary shaft
20: Cutting blade
20a: Lower cutting blade
20b: Lower cutting blade
21: Rotary shaft

1. An on-press development type lithographic printing plate precursor comprising an aluminum support having an anodized film and an image-recording layer provided on the support, wherein a shear droop shape in which an amount X of shear droop is from 25 to 150 μm and a width Y of shear droop is from 70 to 300 μm is provided at an edge portion of the lithographic printing plate precursor, an area ratio of cracks present on a surface of the anodized film in a region corresponding to the width Y of shear droop of the lithographic printing plate precursor is 6% or less, an amount of the anodizing film in a region corresponding to the width Y of shear droop of the lithographic printing plate precursor is from 0.2 to 2.2 g/m², and an average diameter of micropores present on a surface of the anodized film in a region corresponding to the width Y of shear droop of the lithographic printing plate precursor is from 15 to 40 nm.

2. An on-press development type lithographic printing plate precursor comprising an aluminum support having an anodized film and an image-recording layer provided on the support, wherein a shear droop shape in which an amount X of shear droop is from 25 to 150 μm and a width Y of shear droop is from 70 to 300 μm is provided at an edge portion of the lithographic printing plate precursor, an area ratio of cracks present on a surface of the anodized film in a region corresponding to the width Y of shear droop of the lithographic printing plate precursor is 6% or less, an amount of the anodizing film in a region corresponding to the width Y of shear droop of the lithographic printing plate precursor is from 0.2 to 2.2 g/m², and the amount X of shear droop is from 30 to 50 μm.

3. The on-press development type lithographic printing plate precursor as claimed in claim 1, wherein the amount X of shear droop is from 30 to 50 μm.

4. The on-press development type lithographic printing plate precursor as claimed in claim 1, wherein an average width of cracks present on a surface of the anodized film in a region corresponding to the width Y of shear droop of the lithographic printing plate precursor is 20 μm or less.

5. The on-press development type lithographic printing plate precursor as claimed in claim 2, wherein an average width of cracks present on a surface of the anodized film in a region corresponding to the width Y of shear droop of the lithographic printing plate precursor is 20 μm or less.

6. The on-press development type lithographic printing plate precursor as claimed in claim 3, wherein an average width of cracks present on a surface of the anodized film in a region corresponding to the width Y of shear droop of the lithographic priming plate precursor is 20 μm or less.

7. The on-press development type lithographic printing plate precursor as claimed in claim 1, wherein micropores of the anodized film in a region corresponding to the width Y of shear droop of the lithographic printing plate precursor are configured from a large-diameter portion extending from a surface of the anodized film to a depth of 10 to 1,000 nm and a small-diameter portion which communicates with a bottom of the large-diameter portion and extends from a communication part to a depth of 20 to 2,000 nm, and an average diameter of the small-diameter portion at the communication part is 13 nm or less.

8. The on-press development type lithographic printing plate precursor as claimed in claim 2, wherein micropores of the anodized film in a region corresponding to the width Y of shear droop of the lithographic printing plate precursor are configured from a large-diameter portion extending from a surface of the anodized film to a depth of 10 to 1,000 nm and a small-diameter portion which communicates with a bottom of the large-diameter portion and extends from a communication part to a depth of 20 to 2,000 nm, and an average diameter of the small-diameter portion at the communication part is 13 nm or less.

9. The on-press development type lithographic printing plate precursor as claimed in claim 3, wherein micropores of the anodized film in a region corresponding to the width Y of shear droop of the lithographic printing plate precursor are configured from a large-diameter portion extending from a surface of the anodized film to a depth of 10 to 1,000 nm and a small-diameter portion which communicates with a bottom of the large-diameter portion and extends from a communication part to a depth of 20 to 2,000 nm, and an average diameter of the small-diameter portion at the communication part is 13 nm or less.

10. The on-press development type lithographic printing plate precursor as claimed in claim 1, wherein the image-recording layer contains a polymer particle.

11. The on-press development type lithographic printing plate precursor as claimed in claim 2, wherein the image-recording layer contains a polymer particle.

12. The on-press development type lithographic printing plate precursor as claimed in claim 3, wherein the image-recording layer contains a polymer particle.

13. The on-press development type lithographic printing plate precursor as claimed in claim 10, wherein the polymer particle is a polymer particle containing a monomer unit derived from a styrene compound and/or a monomer unit derived from a (meth)acrylonitrile compound.

14. The on-press development type lithographic printing plate precursor as claimed in claim 11, wherein the polymer particle is a polymer particle containing a monomer unit derived from a styrene compound and/or a monomer unit derived from a (meth)acrylonitrile compound.

15. The on-press development type lithographic printing plate precursor as claimed in claim 12, wherein the polymer particle is a polymer particle containing a monomer unit derived from a styrene compound and/or a monomer unit derived from a (meth)acrylonitrile compound.

16. The on-press development type lithographic printing plate precursor as claimed in claim 1, wherein the image-recording layer further contains a polymerization initiator, an infrared absorbing agent and a polymerizable compound.

17. The on-press development type lithographic printing plate precursor as claimed in claim 2, wherein the image-recording layer further contains a polymerization initiator, an infrared absorbing agent and a polymerizable compound.

18. The on-press development type lithographic printing plate precursor as claimed in claim 3, wherein the image-recording layer further contains a polymerization initiator, an infrared absorbing agent and a polymerizable compound.

19. A method for producing a lithographic printing plate comprising a step of imagewise exposing the on-press development type lithographic printing plate precursor as claimed in claim 1 with an infrared laser, and a step of removing an unexposed area of the image-recording layer by at least one selected from printing ink and dampening water on a printing press.

20. A method for producing a lithographic printing plate comprising a step of imagewise exposing the on-press development type lithographic printing plate precursor as claimed in claim 2 with an infrared laser, and a step of removing an unexposed area of the image-recording layer by at least one selected from printing ink and dampening water on a printing press.
